(19) United States
(12) Patent Application Publication
(10) Pub. No.: US 2024/0405148 A1
(43) Pub. Date: Dec. 5, 2024

(54) MONOLITHIC MULTI-WAVELENGTH OPTICAL DEVICES

(71) Applicant: Analog Devices, Inc., Wilmington, MA (US)

(72) Inventor: Ryan M. IUTZI, Somerville, MA (US)

(21) Appl. No.: 18/698,955

(22) PCT Filed: Oct. 3, 2022
(86) PCT No.: PCT/US2022/045528

§ 371 Date: Apr. 5, 2024

Related U.S. Application Data
(60) Provisional application No. 63/252,836, filed on Oct. 6, 2021.

(51) Int. Cl. H01L 31/12; G01N 21/3504; G01N 21/3581; H01L 31/0224; H01L 31/0304; H01L 31/0352

(52) U.S. Cl. CPC H01L 31/125; G01N 21/3504; G01N 21/3581; H01L 31/022408; H01L 31/0304; H01L 31/035236

(57) ABSTRACT

Systems, devices, and methods for optical sensing applications. An example multi-wavelength light emitter structure including a substrate; and a vertical structure over the substrate and extending vertically away from the substrate along an axis, the vertical structure comprising a first active region including one or more cascade stages of superlattices for light emission at a first wavelength; a second active region including one or more cascade stages of superlattices for light emission at a second wavelength different from the first wavelength, wherein the second active region is closer to the substrate than the first active region and spaced apart from the first active region; and an electrically conductive material along sidewalls of at least one of the first active region or the second active region.

### CROSS REFERENCE TO RELATED APPLICATIONS

This application claims priority to and the benefit of U.S. Provisional Patent Application No. 63/252,836 entitled “MONOLITHIC DUAL-WAVELENGTH LIGHT EMITTING DIODE” and filed Oct. 6, 2021, which is hereby incorporated by reference in its entirety as if fully set forth below and for all applicable purposes. This application is also related to U.S. Provisional Application No. 63/227,759 entitled, “DIFFERENTIAL PATH LENGTH SENSING USING MONOLITHIC, DUAL-WAVELENGTH LIGHT EMITTING DIODE” filed on Jul. 30, 2021, U.S. patent application Ser. No. 17/327,172 entitled, “FULLY COMPENSATED OPTICAL GAS SENSING SYSTEM” filed on May 21, 2021, U.S. patent application Ser. No. 15/993,188 now U.S. Pat. No. 10,866,185 entitled, “COMPACT OPTICAL GAS DETECTION SYSTEM AND APPARATUS” filed on May 30, 2018, and U.S. patent application Ser. No. 16/872,758 entitled, “GAS DETECTION USING DIFFERENTIAL PATH LENGTH MEASUREMENT” filed on May 12, 2020, all of which are hereby incorporated by reference in their entirety.

### TECHNICAL FIELD OF THE DISCLOSURE

The present disclosure relates to portable gas detection. More specifically, this disclosure describes apparatuses and systems for multi-wavelength light emitters and/or multi-wavelength photodetectors for optical sensing.

### BACKGROUND

A nondispersive infrared sensor (or NDIR sensor) is a simple spectroscopic sensor often used as a gas detector. It is nondispersive in the sense of optical dispersion since the infrared energy is allowed to pass through the atmospheric sampling chamber without deformation.

It is also nondispersive in the fact that no dispersive element (e.g., a prism or diffraction grating as is often present in other spectrometers) is used to separate out (like a monochromator) the broadband light into a narrow spectrum suitable for gas sensing. The majority of NDIR sensors use a broadband lamp source and an optical filter to select a narrow band spectral region that overlaps with the absorption region of the gas of interest. In this context, a narrow spectral region may refer to a 50-300 nanometer (nm) bandwidth. Modern NDIR sensors may use Microelectromechanical systems (MEMs) or mid infrared (IR) light-emitting diode (LED) sources, with or without an optical filter.

The main components of a nondispersive infrared sensor (NDIR) sensor are an infrared source (lamp), a sample chamber or light tube, a light filter and an infrared detector. The IR light is directed through the sample chamber towards the detector. In parallel there is another chamber with an enclosed reference gas, typically nitrogen. The gas in the sample chamber causes absorption of specific wavelengths according to the Beer-Lambert law, and the attenuation of these wavelengths is measured by the detector to determine the gas concentration. The detector has an optical filter in front of it that eliminates all light except the wavelength that the selected gas molecules can absorb.

Ideally other gas molecules do not absorb light at this wavelength, and do not affect the amount of light reaching the detector however some cross-sensitivity is inevitable. For instance, many measurements in the IR area are cross sensitive to dihydrogen monoxide (H2O), so gases like carbon dioxide (CO2), sulfur dioxide (SO2), and nitrogen dioxide (NO2) often initiate cross sensitivity in low concentrations.

A common application is to use a NDIR (nondispersive infrared absorbance) sensorto monitor CO2. Most molecules can absorb infrared light, causing them to bend, stretch or twist. The amount of IR light absorbed is proportional to the concentration. The energy of the photons is not enough to cause ionization, and thus the detection principle is very different from that of a photoionization detector (PID). Ultimately, the energy is converted to kinetic energy, causing the molecules to speed up and thus heat the gas. A familiar IR light source is an incandescent household bulb. Each molecule absorbs infrared light at wavelengths representative of the types of bonds present.

Many techniques have been proposed which typically include a broadband light source. Unfortunately, they require relatively long optical paths which reduce light collection efficiencies. The inventor of the present disclosure has identified these shortcomings and recognized a need for a more elegant, robust, compact optical gas detection measurement system with high collection efficiency. That is, the inventor has come up with a compact, low-power, optical gas detection apparatus which can be mass produced via packaging without yielding accuracy.

Additionally, the current state of the art uses color wheels or filters disposed at the photodetectors. Specifically, one color (at wavelength, λ₁) is measured for an absorption for a particular gas. The reference measure is typically taken at another color (at wavelength, λ₂) via a color wheel or a second sensor with a filter centered at, λ₂. Gas concentration per unit volume is based upon absorption spectroscopy. However, these techniques may fail to account for the variation of several parameters, in particular, thermal drift, filter bandwidth and sensitivity, variance of the source as a function of wavelength, etc.

This overview is intended to provide an overview of subject matter of the present patent application. It is not intended to provide an exclusive or exhaustive explanation of the invention. Further limitations and disadvantages of conventional and traditional approaches will become apparent to one of skill in the art, through comparison of such systems with some aspects of the present invention as set forth in the remainder of the present application with reference to the drawings.

### SUMMARY OF THE DISCLOSURE

Embodiments of the present disclosure provides an ultra-compact and highly stable and efficient optical measurement system based on principals of optical absorption spectroscopy using substantially collinear pathways. For example, the system may include a light source constructed from a single (or monolithic) epitaxially integrated structure that emits light in separate spectral bands individually addressable in the mid-wave infrared (MWIR) and/or long-wave infrared (LWIR) but from a substantially similar spatial location. The system may include a detector constructed from a single (or monolithic) epitaxially integrated structure that detects light in separate spectral bands (e.g., in the MWIR or LWIR regime).

The use of a monolithically-integrated device for addressable two-color emission from the same die can advantageously enable control over the spectral profiles so as to optimize signal-to-noise ratio, while also ensuring the path-length is as similar as possible for both wavelengths so as to maximize the system's ability to compensate fluctuations. This results in a sensor that can achieve a substantial improvement on the stability of the detection over changes in temperature, humidity, stress, device aging, as well as other environmental factors.

According to one aspect of the present disclosure, a MWIR/LWIR 2-color emitting structure or device (e.g., LED) includes an epitaxial (epi) structure. The epi structure includes one or more cascade stages.

According to another aspect of the present disclosure, the stages are separated into two distinct vertically separated active regions (upper and lower).

According to another aspect of the present disclosure, each region comprises cascade stages of superlattice designed for a specific center wavelength, with a different center-wavelength target between the upper active region stages and the lower active region stages.

According to another aspect of the present disclosure, the upper active region minimally absorbs the light from the lower active region, or vice versa if the LED is intended to be packaged with the epi-surface facing down.

According to another aspect of the present disclosure, the active regions are connected by an electrically conductive material that is part of the epitaxial stack, such as gallium antimonide (GaSb), or indium arsenide (InAs), or an alloy, or a superlattice itself, and forms a contact to both active regions, and can form an external contact to a metal.

According to another aspect of the present disclosure, the doping of the active regions is such that polarities are in opposite directions (along the same axis: one active region is in the p-n or p-i-n configuration, and the other is in the n-p or n-i-p configuration).

According to another aspect of the present disclosure, the two-color device includes three terminals, each formed from a metal layer.

According to another aspect of the present disclosure, a first terminal contacts the middle connection region via etching to the middle layer (mid contact), a second terminal contacts the top layer of the upper active area (top contact), and a third terminal contacts the lower active region either by contacting the top of the substrate just below the layer via etching, or by forming a backside-contact to the opposite side of the substrate (bottom contact).

According to one or more aspects of the present disclosure, an alternate two-terminal configuration in which only a top active layer (top contact) and lower active layer contact (bottom contact) is formed.

According to another aspect of the present disclosure, the sidewall of the active regions is intentionally made to be electrically conductive, either through formation of surface conducting states resulting from defects related to the layers attached to it, or induced through a process step such as annealing, or achieved through a thin conductive layer that is deposited onto the sidewalls.

According to another aspect of the present disclosure, a device configuration includes metal covers all areas and sidewalls except for a window at the very top surface, such that light from both superlattice must be emitted from the same window.

According to yet another aspect of the present disclosure, a photodetector structure or device with the same configuration as the MWIR/LWIR 2-color emitting structure discussed above or other exemplary aspects is operated in a photodetector mode as a means of detecting two separate wavelength light sources from a similar 2-color LED, or from a light source with similar wavelengths.

According to another aspect of the photodetector structure or device, two separate and independent measurements can be taken for each path and each color by measuring the photocurrent in each active region independently, via measuring the current across the active region's corresponding terminals in a three-terminal configuration, or by applying a bias in a two-terminal configuration such that the current across the terminals is dominated by the reverse-bias current of the active region of interest.

According to another aspect of the photodetector structure or device, the measurement from the narrower-bandgap active region may see a signal from light coming from both colors, while the measurement from the wider bandgap active region may only see a signal from the shorter wavelength color, or may see a signal from the shorter wavelength passband at a substantially higher proportion to the longer wavelength passband.

According to another aspect of the photodetector structure or device, for measurement of the longer-wavelength color, the photodetector signal from the wider-bandgap region can be subtracted from the photodetector signal from the narrower bandgap region, to remove some or all of the effect of light of the longer wavelength in the shorter wavelength passband, improving the effective isolation of the two spectra.

According to another aspect of the present disclosure, the devices discussed above or any other aspect can optionally include where the middle region, or an additional region between the lower and upper active regions, comprises a superlattice periodicity or material such that the shorter wavelength tail of light emission from the narrower-bandgap active region is absorbed, resulting in less spectral overlap between the two colors. The additional absorbing region can result in additional improvement of spectral overlap coming from the PD in addition to the LED.

According to another aspect of the present disclosure, where a mode of operation of the 2-color LED in which locally heating of the LED with high currents, or with an external heating element is used to induce small bandgap changes in the active regions, or the use of high current achieves the same effect through the band-filling effect, in order to obtain additional wavelengths shifted from the original wavelengths, hence achieving more than two total colors of emission.

According to another aspect of the present disclosure, the use of the device of the previous aspect in the photodetector mode, in which the same function is used to obtain shifts in the spectral responsivity curve, allowing for additional measurements with different spectral responses.

According to another aspect of the present disclosure, embodiments in which more than 2 wavelengths are emitted by adding additional active regions to the epitaxy and additional contacts to the LED, allowing for multiple reference channels, or multiple main sensing channels, or some combination in which each channel provides a different ratio of main sensing to reference sensing in a manner that adds to the overall compensation ability of the system.

According to another aspect of the present disclosure, the device of the previous aspect in photodetector mode, in which numerous measurements can be made that sample different spectral regions.

According to one aspect of the present disclosure, agas absorption measurement device, measurement of the differential path length ratio at two wavelengths—the first wavelength is disposed at the wavelength of absorption of the target gas and the second wavelength is disposed such that it is not absorbed at any of the gases present in the measurement gas mixture.

According to another aspect of the present disclosure, the gas absorption measurement device, both wavelengths follow substantially identical optical path through the gas sampling optics starting with the optical filter.

According to another aspect of the present disclosure, the gas absorption measurement device in which a second LED is placed in close proximity to the first LED and first LED acts like a secondary reflector to the second LED such that the optical path of the light rays from the second LED after scattering of the first LED is substantially identical.

According to another aspect of the present disclosure, the gas absorption measurement device in which the first LED is placed below or stacked on top of the second LED, or vice versa.

According to another aspect of the present disclosure, the gas absorption measurement device in which one physical LED produces two different wavelengths controllable by electric current.

According to another aspect of the present disclosure, the gas absorption measurement device in which the first LED and filter together have absorption region beyond the target gas to include another gas while the second LED and the filter has absorption only at the other gas.

According to one aspect of the present disclosure, the gas absorption measurement device (or working fluid absorption device) comprises a light source forming a common light path, one or more filters filtering the common light path, a collimator disposed in the common light path, a beam splitter to split the common light path and two or more detectors, each of which to collect the split light path.

According to another aspect of the present disclosure, the gas absorption measurement device (or working fluid absorption device) is configured to dispose the two or detectors at two (or more accordingly) different distances from the light source with each detector measuring light transmission after two different gas absorption path lengths.

According to another aspect of the present disclosure, the gas absorption measurement device (or working fluid absorption device) further comprises collector optic before the detectors.

According to another aspect of the present disclosure, the gas absorption measurement device (or working fluid absorption device), the beam splitter can be a polarizing beam splitter (PBS), a half-wave plate, a half-silvered mirror, a Fresnel prism, or any other suitable optic.

According to another aspect of the present disclosure, the gas absorption measurement device (or working fluid absorption device) further comprises one or more waveguides.

According to another aspect of the present disclosure, the waveguides provide for openings for the diffusion of gas molecules.

According to another aspect of the present disclosure, the optical filter can include an absorptive filter and/or interference or dichroic filter.

According to another aspect of the present disclosure, the light source can include a light emitting device (LED) or other suitable device.

According to another aspect of the present disclosure, the collection optics can include a convex or concave lens.

According to another aspect of the present disclosure, the detectors are photosensitive elements and can be one or more of the following: photodetectors, photodiodes (PDs), avalanche photodiodes (APDs), single-photon avalanche photodiode (SPADs), photomultipliers (PMTs).

According to another aspect of the present disclosure, the differences in the path length is employed after filtering of the light source for a specific gas absorption.

According to another aspect of the gas absorption measurement device (or working fluid absorption device), a ratio of the two detector signals is used to measure the concentration of the working fluid.

According to another aspect of the gas absorption measurement device (or working fluid absorption device), the ratio of the two detectors is saved during calibration step with known condition and subsequently used for future calculations.

According to another aspect of the gas absorption measurement device (or working fluid absorption device), concentration of a predetermined gas is calculated.

According to another aspect of the present disclosure, the predetermined gas may be CO2, water vapor, methane (CH4), nitric oxide (NO), as well as vapors of various alcohols.

According to another aspect of the present disclosure, the predetermined gas may be any of the gases used in anesthesia.

According to another aspect of the present disclosure, the predetermined gas may be vapors of diesel, kerosene, or gasoline.

According to another aspect of the present disclosure, multiple gases may be simultaneously detected by using multiple detectors with optical filters chosen for each of the gases and using a broadband light source.

According to another aspect of the present disclosure, the predetermined gases may be CO2 and alcohol vapor which are simultaneously detected for breadth analysis.

According to another aspect of the present disclosure, the predetermined gases may be water and alcohol vapor which are simultaneously detected for breadth analysis.

According to another aspect of the disclosure, the gas absorption measurement device (or working fluid absorption device) is disposed on a substrate.

According to another aspect of the present disclosure, the gas absorption measurement device (or working fluid absorption device) further comprises an optical cap to which is affixed to the substrate.

According to another aspect of the present disclosure, the inner shape of the cap forms a mirror in which the mirror shape is derived from the two elliptical mirror surfaces inclined substantially at 45 degrees to provide high collection of the light source to the detector.

According to another aspect of the present disclosure, the cap provides for openings for the diffusion of gas molecules.

According to another aspect of the present disclosure, the substrate and the cap provide a method of alignment to each other.

According to another aspect of the present disclosure, the opto-electronic package for measurement of absorption of light further comprises a substrate with at least two detectors disposed thereon.

According to another aspect of the present disclosure, wherein the first detector acts as a reference detector that is measures light such that its signal is substantially insensitive to the absorption by a predetermined gas.

According to another aspect of the present disclosure, the second detector that may have either optical filter attached to it or provided on top of it to make it substantially sensitive to the absorption by the predetermined gas.

According to another aspect of the present disclosure, the opto-electronic package for measurement of absorption of light further comprises many detectors in which at least one detector acts as a reference detector and the other detectors optical filters have applied to them so as to detect different gases present in the cavity.

According to another aspect of the present disclosure, the light source may be a thermal light source.

According to another aspect of the present disclosure, the opto-electronic package for measurement of absorption of light further comprises a substrate with a light source disposed on it. LED may have a center wavelength from 0.2-12 micrometers (μm).

According to another aspect of the present disclosure, the detector may use direct photon absorption or may use indirect method of measurement that includes conversion to heat to measure light flux.

According to another aspect of the present disclosure, direct photon detectors include detectors made from lead selenide (PbSe), phosphate-buffered saline(PbS), mercury cadmium telluride (HgCdTe), GaSb/InAs superlattice etc.

According to another aspect of the present disclosure, indirect thermal detectors include pyroelectrics, bolometers, etc.

According to another aspect of the present disclosure, the opto-electronic package for measurement of absorption of light further comprises that the openings to the cavity that forms the cap may be covered with fine mesh to prevent larger dust particles from entering the cavity.

According to another aspect of the present disclosure, the opto-electronic package for measurement of absorption of light further comprises that the package is constructed with “base package” that can be tested separately from the gas chamber and the two combined by assembly to form the complete gas detection system.

The drawings show exemplary gas detections circuits and configurations. Variations of these circuits, for example, changing the positions of, adding, or removing certain elements from the circuits are not beyond the scope of the present invention. The illustrated smoke detectors, configurations, and complementary devices are intended to be complementary to the support found in the detailed description.

### BRIEF DESCRIPTION OF THE DRAWINGS

The present disclosure is best understood from the following detailed description when read with the accompanying figures. It is emphasized that, in accordance with the standard practice in the industry, various features are not necessarily drawn to scale, and are used for illustration purposes only. Where a scale is shown, explicitly or implicitly, it provides only one illustrative example. In other embodiments, the dimensions of the various features may be arbitrarily increased or reduced for clarity of discussion.

For a fuller understanding of the nature and advantages of the present invention, reference is made to the following detailed description of preferred embodiments and in connection with the accompanying drawings, in which:

FIG. 1 depicts an exemplary two-color measurement system for measuring gas concentration using absorption spectroscopy, in accordance with some embodiments of the disclosure provided herein;

FIG. 2 depicts an exemplary differential path length measurement system for measuring gas concentration using beam splitting mirrors, in accordance with other embodiments of the disclosure provided herein;

FIG. 3 depicts an exemplary differential path length measurement system using alternate beam path optics, in accordance with some embodiments of the disclosure provided herein;

FIG. 4A depicts an exemplary monolithically integrated, three-terminal device, in accordance with one or more embodiments of the disclosure provided herein;

FIG. 4B illustrates the spectrum of an exemplary monolithically integrated, three-terminal device, in accordance with one or more embodiments of the disclosure provided herein;

FIG. 5 depicts an exemplary cross-cut perspective of a monolithically integrated, two-terminal device, in accordance with other embodiments of the disclosure provided herein;

FIG. 6 depicts an exemplary cross-sectional view of a monolithically integrated, two-color device, in accordance with one or more embodiments of the disclosure provided herein;

FIG. 7 depicts an exemplary cross-cut perspective of a monolithically integrated, two-color device, in accordance with one or more embodiments of the disclosure provided herein;

FIG. 8A represents the basis of a differential path length measurement system using coaxial beam path optics, in accordance with one or more embodiments of the disclosure provided herein;

FIG. 8B depicts an exemplary absorbing color in a differential path length measurement system using coaxial beam path optics, in accordance with one or more embodiments of the disclosure provided herein;

FIG. 8C depicts an exemplary reference color in a differential path length measurement system using coaxial beam path optics, in accordance with one or more embodiments of the disclosure provided herein;

FIG. 9 graphically illustrates an exemplary light output spectrum with filter transmission in a differential path length measurement system, in accordance with some embodiments of the disclosure provided herein;

FIG. 10A depicts an exemplary monolithically integrated, three-terminal device, in accordance with some embodiments of the disclosure provided herein; and

FIG. 10B illustrates the spectrum of an exemplary monolithically integrated, three-terminal device, in accordance with some embodiments of the disclosure provided herein.

### DESCRIPTION OF EXAMPLE EMBODIMENTS OF THE DISCLOSURE

### Overview

The present disclosure relates to portable gas detection. More specifically, this disclosure describes apparatuses and systems for optical gas detection using differential path and/or differential wavelength. The inventors of the present disclosure contemplate a monolithically integrated, three-terminal device which gives rise to colinear or coaxially two or more color pathways which wavelength mitigate the difficulties in NDIR, et. al., analyses.

The following description and drawings set forth certain illustrative implementations of the disclosure in detail, which are indicative of several exemplary ways in which the various principles of the disclosure may be carried out. The illustrative examples, however, are not exhaustive of the many possible embodiments of the disclosure. Other objects, advantages and novel features of the disclosure are set forth in the proceeding in view of the drawings where applicable.

In some examples, an LED that emits light in separate spectral bands which are individually addressable in the mid-wave infrared and/or long-wave infrared regime can be constructed from a single epitaxially-integrated structure, such that both bands of light emitted from the device originate from a similar spatial location.

The present disclosure provides techniques to improve on such an emitter for optical sensing applications, in which it is frequently useful to have a main wavelength of light for detection of a phenomena such as gas concentration, particulate, etc., while having a second reference wavelength that can subtract and compensate any other interfering effects such as package deformation, temperature, mechanical stress, lifetime aging, etc. To achieve a dual-wavelength LED that can enable such a sensing mechanism, it is necessary that the light from both colors have nearly identical optical paths, and that spectral overlap of the colors is minimized while still maintaining wavelengths that are relatively close to each other such that other wavelength-dependent properties of the system are minimized.

Such a device enables optical sensing technologies with compensation of background fluctuations to achieve a broader range of operation with respect to environmental conditions and/or greater minimum detection limits.

One of the most popular techniques for quantitative measurement of the industrially significant gases such as CO₂, NOₓ, water vapor, methane etc. is carried out by optical absorption. Most of these gases have strong vibrational absorption spectra in the 1-12 μm region of electromagnetic spectrum and include various vibrational modes and its overtones.

A fundamental measurement technique including measuring changes in the extinction of the light source at a particular wavelength of interest as the concentration of the target gas is varied. This technique is popularly called nondispersive infrared (NDIR) technique.

Many devices are available on the market. They typically include a broadband light source—thermal such as a light bulb or a compact heater or an LED—whose output is passed thru an optical system that provides a relatively long path length for absorption of gas and a detector system to measure extinction. Small holes in the optical system allows the gas to diffuse into the light path.

The detector system itself may include two detectors. One detector provides a reference signal and is specifically tuned to reduce or avoid gas absorption lines of interest to measure drift and changes in the light source and condition of the optical channel. The other detector is tuned to the wavelength of absorption of the gas to be measured.

Many configurations of the optical systems have been proposed in the past, and some of these devices are available on the market. One of the most popular gases to be measured is CO₂. In the discussion below on the design of a novel optical package, the focus will be on CO₂ gas to make the discussion specific, but the principal applies to many of the industrially relevant gases mentioned earlier and is quite general.

Furthermore, the present disclosure will focus on systems that use room temperature detectors and are not cooled since cooling adds cost, increases power consumption, and increases system complexity. However, active and/or passive cooling are not beyond the scope of the present invention.

A better method for measuring absolute gas concentration is disclosed. The method applies equally well to absorbance measurement in liquids. This method applies to any fluid (gas or liquid) that can be placed in the path between light source and two detectors.

A large body of literature exists that use reference detector to measure concentration of gas. The largest market is nondispersive IR measurements (NDIR) in which an optical filter is used to isolate the absorbance of the gas of interest.

Some use a single detector and source and pre-calibrated look-up tables to compensate for temperature, humidity, aging etc. while more precise systems use two different detectors with different filter characteristics or vary the filter in time with the same detector.

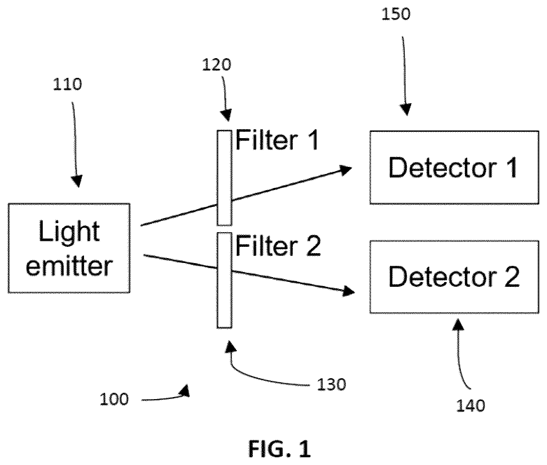

FIG. 1 depicts an exemplary two-color measurement system 100 for measuring gas concentration using absorption spectroscopy, in accordance with some embodiments of the disclosure provided herein. Two-color measurement system 100 comprises light source 110, filter 120, filter 130, reference detector 150, and signal detector 140.

In one or more embodiments, light source 110 is a light emitting diode (LED), such as, an infrared (IR) light emitting diode. However, other embodiments can have light emitting diodes having shorter wavelengths, such as that in the visible or ultraviolet regime. In yet other embodiments, a plurality of multiple wavelengths can be used. Any suitable, compact light producing device is not beyond the scope of the present disclosure—whether, broadband lamps, coherent, incandescent, incoherent bulb, lasers, or even thermal black-body radiation, etc.

In one or more embodiments filter 120/130 is a dichroic filter, at least in part. A dichroic filter, thin-film filter, or interference filter is a very accurate color filter used to selectively pass light of a small range of colors while reflecting other colors. By comparison, dichroic mirrors and dichroic reflectors tend to be characterized by the color(s) of light that they reflect, rather than the color(s) they pass.

While dichroic filters are used in the present embodiment, other optical filters are not beyond the scope of the present disclosure, such as, interference, absorption, diffraction, grating, Fabry-Perot, etc. An interference filter includes multiple thin layers of dielectric material having different refractive indices. There also may be metallic layers. In its broadest meaning, interference filters comprise also etalons that could be implemented as tunable interference filters. Interference filters are wavelength-selective by virtue of the interference effects that take place between the incident and reflected waves at the thin-film boundaries. In other embodiments, a color wheel with an optical chopper can be used as the filter 120.

In practice, light from light source 110 may propagate towards filters 120, 130 and onto detectors 140, 150. The light source is usually broadband, but some embodiments use an infrared (IR) source which is suitable for detecting CO₂ gas. Gas containing CO₂ is passed through a sampling chamber (e.g., between light source 110 and the filters 120, 130) through vents or ports. Some light absorption occurs as a function of the concentration and chemical composition of the target gas. Meaning, different gases absorb light at different wavelengths (bandwidths, really). Accordingly, higher concentrations of targeted gases will absorb more light at that associated wavelength. The goal of any NDIR system is to accurately determine how much light is absorbed/scattered in order to extrapolate the density of gas (i.e., partial pressure of the gas).

The gas in the sample chamber causes absorption of specific wavelengths according to the Beer-Lambert law, and the attenuation of these wavelengths is measured by the detector to determine the gas concentration. Carbon dioxide has a characteristic absorbance band in the infrared (IR) region at a wavelength of 4.26 μm. This means that when IR radiation is passed through a gas including CO₂, part of the radiation is absorbed. Therefore, the amount of radiation passing through the gas depends on the amount of CO₂ present, and this can be detected with an IR detector.

This is accomplished by using two optical bandpass filters 120, 130 and two thermopiles. A thermopile is an electronic device that converts thermal energy into electrical energy. It is composed of several thermocouples connected usually in series or, less commonly, in parallel. Such a device works on the principle of the thermoelectric effect, i.e., generating a voltage when its dissimilar metals (thermocouples) are exposed to a temperature difference.

One bandpass filter 120 is used as a reference band and typically doesn't significantly overlap with the absorption signal band. As previously described, the absorption signal band corresponds to the target gas. The two are compared (e.g., ratio, etc.) and a determination can be made about the concentration of the target gas.

A system such as this typically does need to be calibrated. Specifically, some measurement baseline needs to be taken before target gas detection. Nevertheless, the present system is susceptible to wavelength drift from the light source, which represents one of the shortcomings of the present state of the art.

While versatile in that the present embodiment may detect numerous gases at once, the present system suffers from the previous embodiment. That is, the system requires calibration and is susceptible from wavelength and intensity drift, particularly because it does not have a reference channel measurement.

The idea in the state-of-the-art systems is that the ratio of the reference channel to the filtered channel—corresponding to the specific gas—removes the intensity variation in the source over time as well as common changes in the performance of the detectors. In these methods of measuring gas concentration, shifts in the wavelength spectrum of the light as well as subtle changes in the optical filters cannot be removed directly from the measurement. While alleviating some of the issues of drift, it still requires complex calibration.

Some state-of-the-art systems (e.g., Vaisala) use a Fabry-Perot (FP) cavity-based system, where the same detector is used to receive radiation from a single light source as the filter is tuned alternately between “on gas absorbance” and “off gas absorbance” to measure the gas absorbance. However, this does not properly compensate for the spectral shifts in the light source or the filter. In most of cases of IR measurement of gases, “off-absorption filter” has to be positioned many 100's of nm from the “on-absorption filter” due to the width of the absorption features. This is sufficiently separated in wavelength, that the ratio cannot fully compensate for the spectral shape changes in LED and other light sources overtime and temperature.

In previous designs, the reference channel uses a different filter than the measurement channel to track the light source's intensity variation. In Vaisala's sensor, an FP cavity is used and a filter is tuned to be on and off the gas absorption wavelengths alternatively in time.

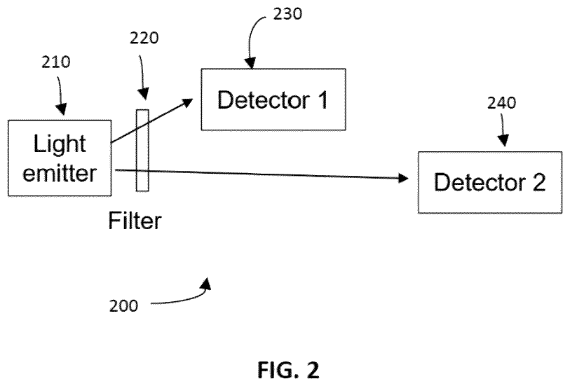

FIG. 2 represents the most common approach—that is, two optical paths, equal in length, with a single light source feeding both paths. Specifically, one path with a filter to give an absorbing portion of the spectrum; the other with an “off-resonance” non-absorbing channel. Yet, it does have its shortcomings. In particular, it is sensitive to temperature-induced drifts in light intensity, requires significant calibration, limited performance.

One of ordinary skill can appreciate the following novel features of the disclosure. Other benefits are not beyond the scope of the present disclosure. The present disclosure is highly independent of the LED and filter performance over temperature, intensity, etc. as well as any changes in the wavelength spectrum of the light source and filters and other optical elements.

Additionally, all spectral changes over are naturally removed from the measurement. This includes changes in intensity either due to electrical or optical system drifts.

The present disclosure provides the benefits of ratio metric measurement cancelling most of the drifts even amongst the two detectors to the extent that the two detectors are identically manufactured.

The present disclosure also provides for highly simplified calibration with a single measurement at a known concentration of the species of interest.

Last, the present disclosure is easy to implement as current solutions are more tractable. As such, calibration procedure is highly simplified during manufacturing.

FIG. 2 depicts an exemplary differential path length measurement system 200 for measuring gas concentration using beam splitting mirrors, in accordance with other embodiments of the disclosure provided herein. Differential path length measurement system 200 comprises light source 210, filter 220, reference detector 230, and signal detector 240.

Differential path length (DPL) automatically cancels the changes in LED and filter's performance characteristics such as changes in intensity or wavelength and makes for a robust measurement of gas absorption. For example, the product of LED intensity in a wavelength range of gas absorption and photodiode responsivity can change by almost 10×-30×over a temperature range of −40 to 70° C. The DPL method eliminates most of this variation and the ratio becomes stable to a few percent over the same temperature range. But there remains residual variation from mechanical changes in the optical path.

Ideally, it may be desirable to make the ratio stable to 0.1% (a maximum change) or better over temperature and other environmental conditions. The residual uncompensated changes in the DPL method seem to originate in the changes in the optical path itself. The disclosed techniques may be built on DPL method and may compensate for the optical path changes as well as any other residual changes in the detector and amplifier to make the measurement of the absorption of gas robust.

Changes in the optical path may lead to changes in the measured intensity that can't be distinguished from changes due to gas absorption (even after using DPL method). These changes may include: Vibration; Temperature induced changes in size and distortion of the optical surfaces; Humidity induced changes in size and distortion of the optical surfaces; Changes in the reflectance of the surfaces; and Changes in the responsivity of the photodiodes as a function of temperature and environment.

FIG. 2 is based on a differential path length: one color emission with two detectors at different path lengths. The ratio of the two detectors cancels out light intensity drifts and tracks gas concentration. However, this design is sensitive to mechanical deformation and other drifts.

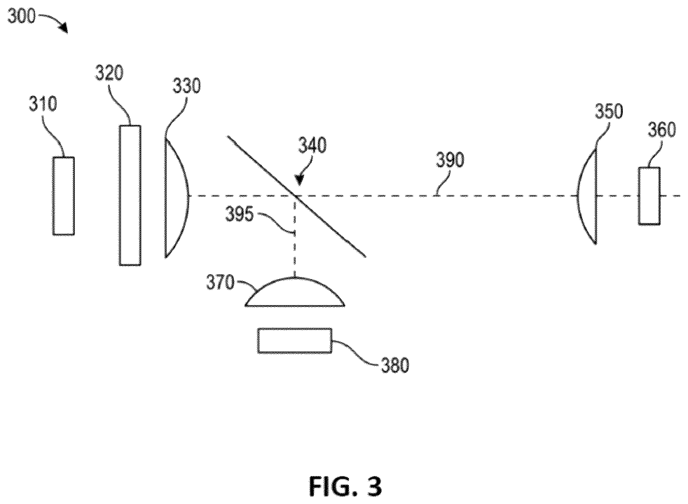

FIG. 3 depicts an exemplary differential path length measurement system 300 for measuring gas concentration using absorption spectroscopy, in accordance with some embodiments of the disclosure provided herein. Differential path length measurement system 300 comprises light source 310, filter 320, collimating lens 330, beamsplitter 340, reference collection lens 370, reference detector 380, signal collection lens 350, and signal detector 360.

In one or more embodiments, light source 310 is a light emitting diode (LED), such as, an infrared (IR) light emitting diode. However, other embodiments can have light emitting diodes having shorter wavelengths, such as that in the visible or ultraviolet regime. In yet other embodiments, a plurality of multiple wavelengths can be used. Any suitable, compact light producing device is not beyond the scope of the present disclosure—whether, broadband lamps, coherent, incandescent, incoherent bulb, lasers, or even thermal black-body radiation, etc.

Collimating lens 330 is a collimator. In optics, a collimator may include a curved mirror or lens with some type of light source and/or an image at its focus. This can be used to replicate a target focused at infinity with little or no parallax. The purpose of the collimating lens 330 is to direct the light rays in a coaxial light path toward beamsplitter 340.

Beamsplitter 340 is a beamsplitter which is known in the art. A beam splitter (or beamsplitter) is an optical device that splits a beam of light in two. It is a crucial part of many optical experimental and measurement systems, such as interferometers, also finding widespread application in fiber optic telecommunications.

In its most common form, a cube, a beamsplitter 340 is made from two triangular glass prisms which are glued together at their base using polyester, epoxy, or urethane-based adhesives. The thickness of the resin layer is adjusted such that (for a certain wavelength) half of the light incident through one “port” (i.e., face of the cube) is reflected and the other half is transmitted due to frustrated total internal reflection. Polarizing beam splitters, such as the Wollaston prism, use birefringent materials to split light into two beams of orthogonal polarization states.

In other embodiments, beamsplitter 340 is a half-silvered mirror. This comprises an optical substrate, which is often a sheet of glass or plastic, with a partially transparent thin coating of metal. The thin coating can be aluminum deposited from aluminum vapor using a physical vapor deposition method. The thickness of the deposit is controlled so that part (typically half) of the light which is incident at a 45-degree angle and not absorbed by the coating or substrate material is transmitted, and the remainder is reflected.

A very thin half-silvered mirror used in photography is often called a pellicle mirror, which can also be used in some embodiments. To reduce loss of light due to absorption by the reflective coating, so-called “swiss cheese” beam splitter mirrors have been used. Originally, these were sheets of highly polished metal perforated with holes to obtain the desired ratio of reflection to transmission. Later, metal was sputtered onto glass so as to form a discontinuous coating, or small areas of a continuous coating were removed by chemical or mechanical action to produce a very literally “half-silvered” surface.

In yet another embodiment, instead of a metallic coating, a dichroic optical coating may be used. Depending on its characteristics, the ratio of reflection to transmission will vary as a function of the wavelength of the incident light. Dichroic mirrors are used in some ellipsoidal reflector spotlights to split off unwanted infrared (heat) radiation, and as output couplers in laser construction.

In still another embodiment, a third version of the beamsplitter 340 is a dichroic mirrored prism assembly which uses dichroic optical coatings to divide an incoming light beam into a number of spectrally distinct output beams. Such a device was used in three-pickup-tube color television cameras and the three-strip Technicolor movie camera. It is currently used in modern three-charge coupled device (CCD) cameras. An optically similar system is used in reverse as a beam-combiner in three-liquid crystal display (LCD) projectors, in which light from three separate monochrome LCD displays is combined into a single full-color image for projection.

As enumerated, any beam splitter or optical circulator can be used. Optical circulators which have the property to conserve power but greatly increase the complexity and cost. However, any suitable optical device, e.g., polarizing beam splitter, half-wave plate, half silvered mirror, etc., is not beyond the scope of the present disclosure.

In practice, collimated light coming from collimating lens 330 get bifurcated into two beams, 395, 390. Beam 395 is used as the reference beam, which beam 390 is used as the signal beam. Their geometries are known, as well as their respective pathlengths. The significance of which will be described in greater detail later in the disclosure.

In one or more embodiments, reference collection lens 370 and signal collection lens 350 are optical lenses. An optical lens is a transmissive optical device that focuses or disperses a light beam by means of refraction. A simple lens may include a single piece of transparent material, while a compound lens may include several simple lenses (elements), usually arranged along a common axis. Lenses are made from materials such as glass or plastic and are ground and polished or molded to a desired shape.

A lens can focus light to form an image, unlike a prism, which refracts light without focusing. Devices that similarly focus or disperse waves and radiation other than visible light are also called lenses, such as microwave lenses, electron lenses, acoustic lenses, or explosive lenses.

Most lenses are spherical lenses: their two surfaces are parts of the surfaces of spheres. Each surface can be convex (bulging outwards from the lens), concave (depressed into the lens), or planar (flat). The line joining the centers of the spheres making up the lens surfaces is called the axis of the lens.

Lenses are classified by the curvature of the two optical surfaces. A lens is biconvex (or double convex, or just convex) if both surfaces are convex. If both surfaces have the same radius of curvature, the lens is equiconvex. A lens with two concave surfaces is biconcave (or just concave). If one of the surfaces is flat, the lens is piano-convex or piano-concave depending on the curvature of the other surface. A lens with one convex and one concave side is convex-concave or meniscus. It is this type of lens that is most commonly used in corrective lenses.

If the lens is biconvex or piano-convex, a collimated beam of light passing through the lens converges to a spot (a focus) behind the lens. In this case, the lens is called a positive or converging lens. For a thin lens in air, the distance from the lens to the spot is the focal length of the lens, which is commonly represented by f in diagrams and equations. An extended hemispherical lens is a special type of plano-convex lens, in which the lens's curved surface is a full hemisphere and the lens is much thicker than the radius of curvature.

If the lens is biconcave or plano-concave, a collimated beam of light passing through the lens is diverged (spread); the lens is thus called a negative or diverging lens. The beam, after passing through the lens, appears to emanate from a particular point on the axis in front of the lens. For a thin lens in air, the distance from this point to the lens is the focal length, though it is negative with respect to the focal length of a converging lens.

Convex-concave (meniscus) lenses can be either positive or negative, depending on the relative curvatures of the two surfaces. A negative meniscus lens has a steeper concave surface and is thinner at the center than at the periphery. Conversely, a positive meniscus lens has a steeper convex surface and is thicker at the center than at the periphery. An ideal thin lens with two surfaces of equal curvature would have zero optical power, meaning that it would neither converge nor diverge light.

All real lenses have nonzero thickness, however, which makes a real lens with identical curved surfaces slightly positive. To obtain exactly zero optical power, a meniscus lens must have slightly unequal curvatures to account for the effect of the lens' thickness.

In practice, both collective lenses serve to focus light onto photodetectors 360, 380, which are sensors of light or other electromagnetic energy. Photodetector 360, 380 have p-n junctions that convert light photons into current. The absorbed photons make electron-hole pairs in the depletion region, which is used to detect received light intensity. In some embodiments, photodetectors 360, 380 are photodiodes or phototransistors. However, any light detecting means, e.g., avalanche, photo-multiplier tube, etc. is not beyond the scope of the present disclosure.

Pursuant to FIG. 3, it can be demonstrated:

$$R = \frac{{S}_{1}}{{S}_{2}} = \frac{LSF {D}_{1} exp ( - {α}_{gas} {c}_{gas} {L}_{1} )}{LSF {D}_{2} exp ( - {α}_{gas} {c}_{gas} {L}_{2} )} = \frac{{D}_{1}}{{D}_{2}} exp ( - {α}_{gas} {c}_{gas} ( {L}_{1} - {L}_{2} ) ) .$$

Thus, we see that all the variations in the light source and the filter cancel. If the ratio

$$\frac{{D}_{1}}{{D}_{2}}$$

of the responsivities of the detectors is known or calibrated at a known concentration of gas, then one can use this to determine directly any concentration of the gas.

This cancellation of light source characteristics makes the entire detection system independent of the intensity as well as spectral variations in the light source over time, temperature, mechanical stresses and many other parameters that might change the characteristics of light source and filter over time.

Calibration step may be written as:

$${R}_{0} = \frac{{D}_{1}}{{D}_{2}} exp ( - {α}_{gas} {c}_{0} ( Δ L ) ) .$$

And the ratio noted and saved as part of the instrument calibration.

Now the measurement at any gas concentration may be determined as:

$$\frac{R}{{R}_{0}} = exp ( - {α}_{gas} ( {c}_{gas} - {c}_{0} ) Δ L ) , or$$

$${c}_{gas} = {c}_{o} + \frac{1}{{α}_{gas} Δ L} log ( \frac{R}{{R}_{0}} ) .$$

There are many implementations that will achieve the differential path of ΔL.

Optical sensing can be used to detect a variety of phenomenon such as molecules, particulates, hydration, etc. A typical embodiment includes a light source that is chosen to have a particular wavelength such that the light will interact with some analyte that results in a change of the lights properties, such as intensity or phase. The light has a path length that involves the sensor itself and the analyte, and at the end of this path length is a detector that then detects the change in light intensity. For example, optical gas sensing can be achieved with a MWIR light source with a spectral output that peaks at or near the gas absorption peaks of the intended analyte gas.

A typical embodiment includes the LED, a filter to attenuate the light to a narrow spectral distribution, a path length through which gas absorption occurs, and a detector that detects the transmitted light (e.g., as discussed above with reference to FIG. 1-3). Other versions, such as hydration or smoke sensing, rely on scattering phenomena instead of absorption. In most cases, some phenomenon occurs in which the detected light on the other side of the path-length is different as a result of the phenomena to be measured. However, there are typically numerous other interfering phenomena which also affect the signal on the end of the path length, making it impossible to distinguish between the desired measured phenomena and other phenomena. For example, in gas sensing, changes in the optical path due to mechanical vibration, thermal stresses, etc., result in a corresponding interference signal that must be compensated or calibrated out.

A second wavelength can provide a means to compensate for interfering phenomena, provided it is subject to the same interfering phenomena but provides a different interaction with the desired detection phenomenon. For example, in gas sensing, a second wavelength can be chosen to be non-absorbing by the analyte gas, but still close enough in wavelength that the optical path is approximately the same with regards to reflections, transmission, scattering from the components in the sensor. As a second example, in a particulate measurement, the scattering will be different for the second wavelength, and while nonzero, the nonzero differential between the two colors will allow for a linear system to solve the compensation of the other interfering effects.

In a vast majority of such applications, there are a few important characteristics enumerated as follows. The colors should be individually addressable, such that a measurement can be taken with one color, and then another, separated in time. Also, the light from both colors need to follow almost an identical optical path, emerging from the same surface, with the same emission area for both colors, and no offset of the emission areas.

Additionally, the light from both colors should be close in wavelength, such that any wavelength-dependent phenomena in the optical path causes a minimal difference in the total coupling efficiency. Last, the light from both colors need to have a minimized spectral overlap with each other, in order to maximize the differential component of the wavelength-dependent phenomena to be measured.

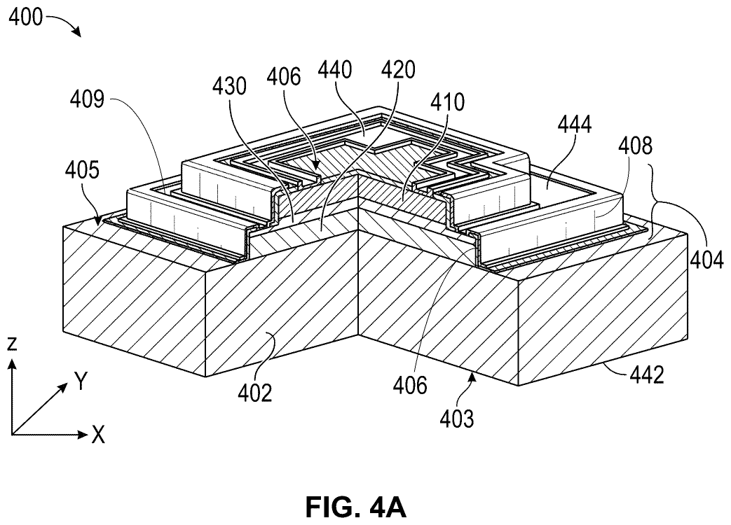

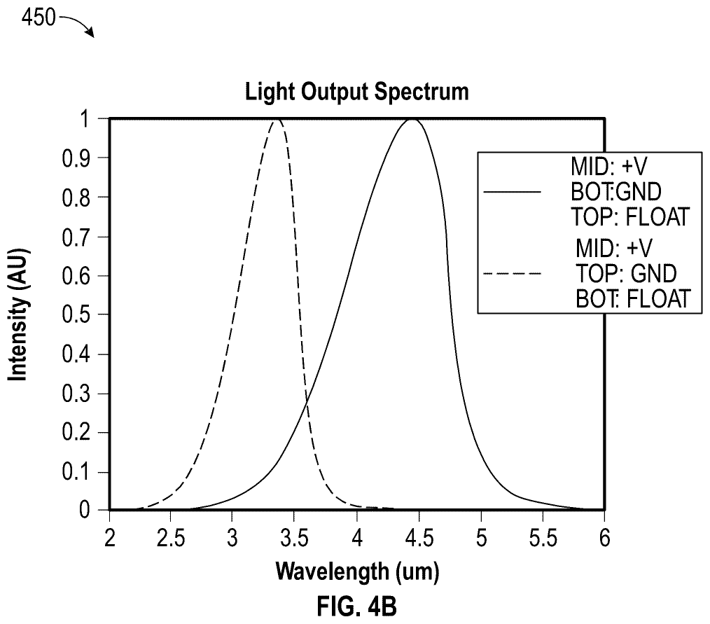

FIGS. 4A, 5-7, and 10A illustrate various configurations of monolithically integrated optical devices (e.g., LED or photodetectors) that can facilitate differential path length-based optical measurements and sensing.

FIG. 4A depicts an exemplary monolithically integrated, three-terminal device 400, in accordance with one or more embodiments of the disclosure provided herein. In some examples, the device 400 is a LED device. In other examples, the device 400 is photodetector device.

As shown in FIG. 4A, the device 400 includes a substrate 402 and a vertical structure 404 (e.g., a vertical epitaxial structure) disposed over a substrate 402. The substrate 402 may be a die or any suitable support structure. The vertical structure 404 may include a plurality of regions or layers stacked on top of each other along an axis (e.g., the z-axis) about perpendicular to a plane (e.g., a top surface or face 405 or a bottom surface or face 403 opposite the top surface or face 405) of the substrate 402. Stated differently, the vertical structure 404 may extend away vertically from the substrate 402 along the z-axis. In the illustrated example of FIG. 4A, the vertical structure 404 includes an upper active region 410 to operate at a first wavelength (a first center wavelength) and a lower active region 410 to operate at a second wavelength (a second center wavelength). The second wavelength is different than the first wavelength. The lower active region 420 is vertically below the upper active region 410 and spaced apart from the upper active region 410. Stated differently, the lower active region 420 is closer to the substrate 402 than the upper active region 410. That is, a distance from the lower active region 420 to the substrate 402 is shorter than a distance from the upper active region 410 to the substrate 402. In an example, the device 400 is an LED, and thus the upper active region 410 may be configured to emit light at the first wavelength and the lower active region 420 may be configured to emit light at the second wavelength. In another example, the device 400 is a photodetector, and thus the upper active region 410 may be configured to detect light at the first wavelength (first center wavelength) and the lower active region 420 may be configured to detect light at the second wavelength (second center wavelength).

The vertical structure 404 further includes a middle region (or layer) 430 between the upper active region 410 and the lower active region 420. In some aspects, the upper active region 410 may include one or more cascade stages of superlattice configured for the first wavelength, and the lower active region 420 may include one or more cascade stages of superlattice configured for the second wavelength. In some aspects, the first and/or the second wavelengths may be a MWIR or a LWIR. In certain aspects, the first and the second wavelengths may be substantially close to each other such that any wavelength-dependent phenomena in the optical path causes a minimal difference in the total coupling efficiency.

In some aspects, the middle region (or layer) 430 may include an electrically conductive material, and the upper active region 410 and the lower active region 420 may be connected to the electrically conductive material. In some aspects, the electrically conductive material comprises at least one of GaSb, InAs, an alloy, or a superlattice.

In some aspects, the upper active region 410 and the lower active region 420 may be doped such that polarities of the upper active region 410 and the lower active region 420, along the z-axis, are in opposite directions. For instance, one of the upper active region 410 or the lower active region 420 may have a p-n configuration or a p-i-n configuration, and the other one of the upper active region 410 or the lower active region 420 may have a n-p configuration or a n-i-p configuration.

As further shown in FIG. 4A, the device 400 may include a first terminal 440 (a top contact), a second terminal 442 (a bottom contact), and a third terminal 444 (a mid-contact). Each of the first terminal 440, the second terminal 442, and the third terminal 444 may include a metal layer (a contact layer). The first terminal 440 may be in contact with a top surface of the upper active region 410. In the illustrated example of FIG. 4A, the second terminal 442 is at a back side or back face 403 of the substrate 402. In other examples, the second terminal 442 can be on a top face 405 of the substrate 402 and just below the lower active region 420. The third terminal 444 can be in contact with the middle region 430. Further, the device 400 may include a dielectric passivation and/or anti-reflective material or coating 406 on top of the upper active region 410 and along sidewalls of the upper active region 410. The dielectric passivation and/or anti-reflective material or coating 406 may also be along sidewalls of the lower active region 420. Sidewalls may refer to surfaces that are substantially parallel to the z-axis and perpendicular to the top face 405 of the substrate 402. Additionally, the lower active region 420 and a portion of the middle region 430 may have a greater dimension in directions along the x-axis and y-axis than the upper active region 410. The dielectric passivation and/or anti-reflective material or coating 406 may be on top of the portion of the middle region 430. Further, the device 400 may include an electrically conductive material 408 (e.g., a metal material) along sidewalls of the upper active region 410, the middle region 430, and the lower active region 420, where the dielectric passivation and/or anti-reflective material or coating 406 may be between the upper active region 410, the middle region 430, and the lower active region 420 and the electrically conductive material 408.

In one or more embodiments, the three-terminal device 400 can emit MWIR and/or LWIR light at two wavelengths that are individually addressable. Typical semiconductor materials for molecular sensing may include GaSb, InAs, InSb, GaAs, AlAs, as well as their possible alloys with each other. Beyond molecular sensing, any semiconductor material can be used to achieve wavelengths outside of the MWIR range, provided they can be grown epitaxially on substrate.

The ability to tailor the bandgap by utilizing superlattices of the layers enables the ability to design different emission regions from the same superlattice material system, while simultaneously minimizing the average strain of the materials. This allows them to be epitaxially integrated into a single epitaxial stack with the ability to limit defect formation. This could also be done using alloys of semiconductor materials to match the strain while tuning the bandgap.

As shown in FIG. 4A, between the two emission regions (e.g., the upper active region 410 and the lower active region 420) is a middle region (or layer) 430 that is designed to electrically connect the two active areas (e.g., the upper active region 410 and the lower active region 420), achieve good electrical contact to a metal for an external contact, be electrically conductive enough to enable good current spreading, be thermally conductive enough to enable good heat dissipation, and be transparent to the light at the wavelengths of interest. This can be achieved with the materials listed above and their alloys, or superlattices similar to the active regions but optimally with a wider bandgap for transparency, in one or more embodiments. The middle layer 430 doping is controlled to minimize free carrier absorption while being electrically conductive enough for the aforementioned considerations. The middle layer 430 is also used to form a common contact which is either a common anode for both emission regions, or a common cathode.

In this example, the device 400 is doped such that middle layer 430 is able to form such a common anode or common cathode. FIG. 4B illustrates a light output spectrum 450 of the exemplary monolithically integrated, three-terminal device 400, in accordance with one or more embodiments of the disclosure provided herein. The light emission that results from the device 400 is shown in FIG. 4B. The light emission can be dependent on a bias scheme. The device 400 need-not have the bottom terminal (or contact) 442 on the die backside or back face 403, although this is often advantageous to implement since it allows for smaller die size.

FIG. 4B is shown for the common anode configuration, but a common cathode configuration can also be done. Similarly, the FIG. 4B scheme becomes GND instead of +V, +V instead of GND, and GND instead of floating. It is also possible to have the device doped such that the middle-region is an anode for one and a cathode for another, but this results in more complicated biasing schemes. For a die packaged to be top-side emitting, it is best to have the upper active area be the wider bandgap material, and vice versa for a backside emitting device.

The device 400 is designed such that the mid-contact (e.g., the third terminal 444) extends above a dielectric sidewall and anti-reflection coating or layer 406, such that it covers the sidewalls of the LED (the device 400) without making an electrical contact outside of the mid-contact 444 region. This blocks light from the lower active layer 420 such that it can only be emitted from the top surface which is the same emission surface as the upper active layer. Stated differently, the vertical structure 404 may include an electrically conductive material (e.g., a metal layer) disposed along sidewalls of the upper active region 410 and the lower active region 420. In some further aspects, the

In this case we take advantage of the fact that the collection optics are designed to collect light from a LED surface that may have extent of couple hundred microns. The light from the entire surface of the LED needs to be collected and imaged onto the detector surface. Thus, two LEDs placed on top one another will be indistinguishable and still form an image on the detector surface. The choice of which wavelength should have a larger LED will be determined by the cost and electrical convenience.

To summarize before proceeding to the next embodiment, one of ordinary skill in the art can appreciate the following aspects. Single-path length gas detectors are prone to drifts in light intensity with temperature, which limit stability and limit how low concentrations can be detected, as well as limit the environmental conditions in which they can operate

A dual-path length configuration can cancel out light intensity drifts, but as a tradeoff, are more prone to mechanical shifts from temperature, drifts in electronics, and aging of the device, which also limit performance and operating conditions.

Utilizing a second color with a reference wavelength may allow for these effects in differential path length to be subtracted out, giving a superior performance device that cancels out most drifts.

The second color may work in a differential path-length configuration if the second color has approximately the same spatial origin as the main color (that is, two side-by-side packaged LEDs does not work), a wavelength that is close the wavelength of the main color, and a spectral that is substantially non-overlapping with the main color.

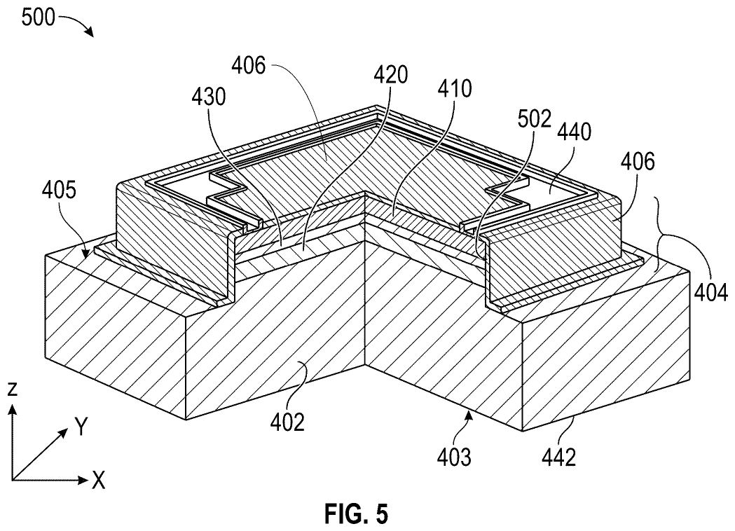

FIG. 5 depicts an exemplary cross-cut perspective of a monolithically integrated, two-terminal device 500, in accordance with other embodiments of the disclosure provided herein. In some embodiments, the device 500 can be made in a two-terminal configuration. The device 500 is similar to the device 400 in many respects but may include two terminals instead of three terminals. For simplicity, FIG. 5 may use the same reference numerals as in FIG. 4A to refer to the same or analogous elements; for brevity, a discussion of these elements is not repeated, and these elements may take the form of any of the embodiments disclosed herein.

As shown in FIG. 5, the device 500 includes two terminals, a terminal 440 (a top contact) and a terminal 442 (a bottom contact). At the device 500, light emission is achieved in an addressable manner by switching between forward and reverse bias (e.g., forward bias at one time and reverse bias at another time). In some examples, a 2-color LED device with two terminals may rely on breakdown current in the reverse-biased device to drive the forward biased device, but for the shorter wavelength end of the MWIR spectrum and beyond, this may result in voltages too high to be acceptable in a low-power sensor. Embodiments of the present disclosure provides an improvement to such a device by utilizing sidewall current along the sidewalls of the active regions, in order to achieve higher drive currents through the reversed biased regions at the same voltage.

To that end, this can be achieved by inducing surface states at the sidewalls 502, which can be formed by using a specific dielectric layer deposited over the sidewalls that induce strain, or promote a certain type of chemical bond, or by functionalizing the sidewalls 502 with a particular chemical, or by abstaining from utilizing sidewall passivation altogether, or from utilizing a high temperature process to induce defects at the surface (of the sidewalls 502), or by depositing a thin conductive material.

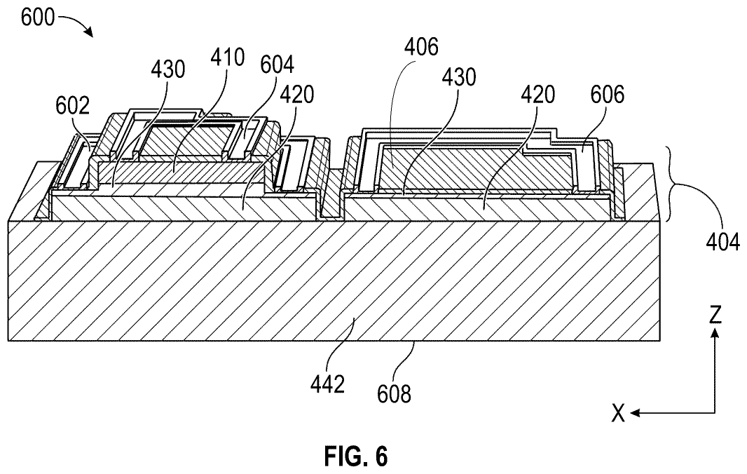

FIG. 6 depicts an exemplary cross-cut perspective of the monolithically integrated, two-color device 600, in accordance with one or more embodiments of the disclosure provided herein. The device 600 is similar to the devices 400 and 500 in many respects. For simplicity, FIG. 6 may use the same reference numerals as in FIGS. 4A and 5 to refer to the same or analogous elements; for brevity, a discussion of these elements is not repeated, and these elements may take the form of any of the embodiments disclosed herein. Compared to the device 400, the device 600 may include four terminals: a color-1 anode 602, a color-1 cathode 604, a color-2 anode 606, and a color-2 cathode 608, respectively, where color-1 may be emitted by the upper active region 410, and color-2 may be emitted by the lower region 420.

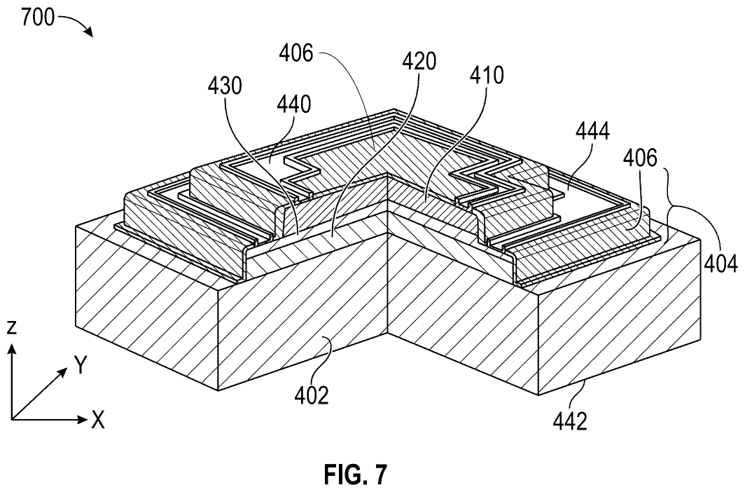

FIG. 7 depicts an exemplary cross-sectional view of the monolithically integrated, two-color device 700, in accordance with one or more embodiments of the disclosure provided herein. The device 700 is similar to the devices 400, 500, and 600 in many respects. For simplicity, FIG. 7 may use the same reference numerals as in FIGS. 4A, 5, and 6 to refer to the same or analogous elements; for brevity, a discussion of these elements is not repeated, and these elements may take the form of any of the embodiments disclosed herein. The device 700 may include a dielectric passivation and/or anti-reflective coating 406 along sidewalls of upper active region 410, the middle region 430, and the lower active region 420.

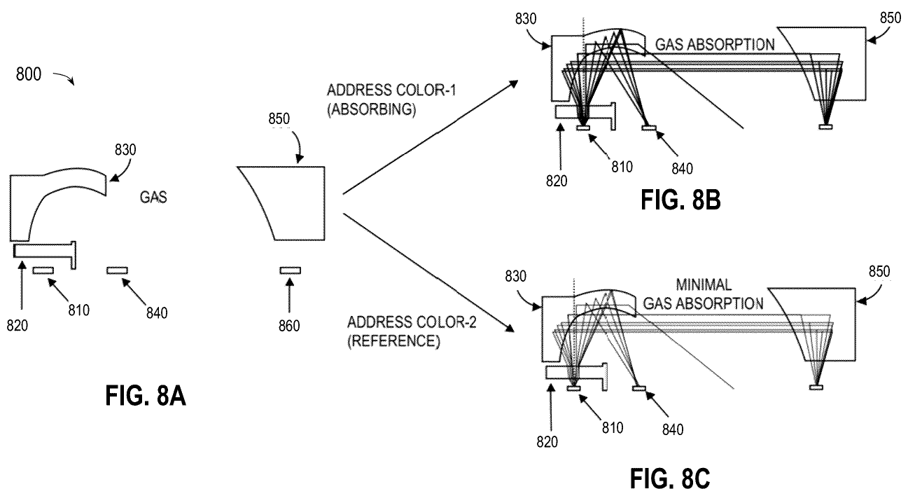

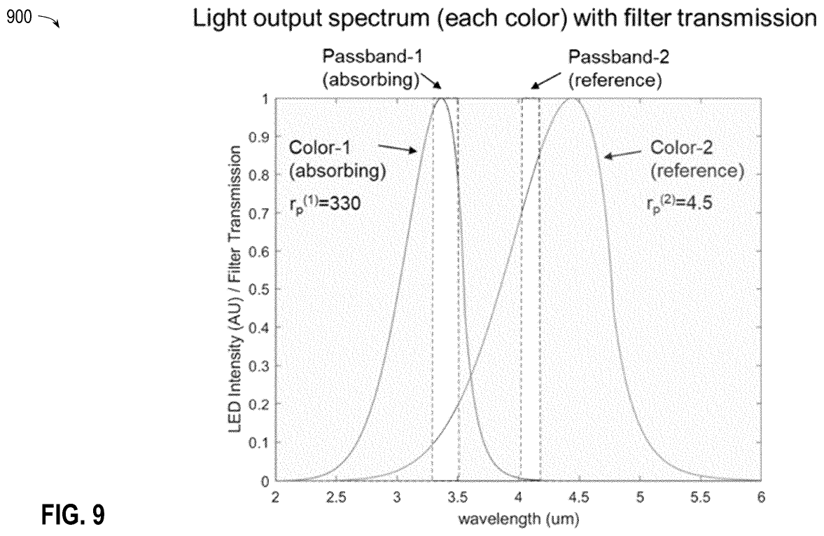

FIG. 8A represents the basis of a differential path length measurement system 800 using coaxial beam path optics, in accordance with one or more embodiments of the disclosure provided herein. Differential path length measurement system 800 comprises a dual wavelength LED 810, a dual-pass band optical filter 820, mirror 830, reference detector 840, mirror 850, and main detector 860.

In one or embodiments, the dual wavelength LED 810 is a stacked active semiconductor which produces collinear light two-color light at a direction orthogonal to the surface of device, although other light sources are not beyond the scope of the present disclosure. For example, a broadband light source could conceivably be used provided the dual-pass band optical filter 820 sufficiently teased out two suitable colors, one that gets absorbed by the gas to be detected and another which is inert and acts like a reference.

In some embodiments, light propagating from dual wavelength LED 810 gets further clarified into two bandwidths with the dual-pass band optical filter 820, as characterized above. One skilled in the art that this adds a degree of precision to measurement accuracy but the result could be achieved without it. In some embodiments, dual-pass band optical filter 820 is a multiband bandpass interference filter, however any suitable filter is not beyond the scope of the present disclosure.

Light transmitted through dual-pass band optical filter 820 is reflected off of mirror 830. Mirror 830 can be any reflecting surface which directs the light toward (through) the gas detection chamber, although in practice, conic section shaped mirrors yield better results. Specifically, mirror 830 has the shape of one or more conic sections. The first focuses light across the chamber to mirror 850. A second concave shape helps concentrate part of the light on reference detector, although any suitable shape is not beyond the scope of the present disclosure. These light pathways are represented in FIGS. 8B-7C. Two- and three-dimensional parabolas/paraboloids and ellipses/ellipsoids are preferred in some embodiments. Yet other conic sections and other shapes and surfaces are not beyond the scope of the present disclosure. For example, a polarizing beamsplitter (PBS) with plane mirrors could be used.

Mirror 850 helps focus the incident collimated light onto the main detector 860. Both main detector 860 and reference detector 840 can measure both colors of light giving rise to four or more measurements.

FIG. 8B depicts an exemplary absorbing color in the differential path length measurement system 800 using coaxial beam path optics, in accordance with one or more embodiments of the disclosure provided herein. FIG. 8B is representative of the propagation, adsorption and measurement of wavelength which actively interacts with a predetermined gas. As can be appreciated by one skilled in the art, the selected wavelength is chosen such that it may be absorbed by a gas which is to detected.

FIG. 8C depicts an exemplary reference color in a differential path length measurement system 830 using coaxial beam path optics, in accordance with one or more embodiments of the disclosure provided herein. FIG. 8C is representative of the propagation and measurement of wavelength which is inert with a predetermined gas. As can be appreciated by one skilled in the art, the selected wavelength is chosen such that it does not interact with a gas which is to be detected

In one or embodiments, a differential path length configuration comprises two color channels. The light is emitted from a single die/location, that can emit either an absorbing color, or a reference color, depending on configuration.

This is made to achieve the same spatial origin of the light, close wavelengths, minimal spectral overlap of the wavelengths. The system is configured to measure all four measurements (color-1 on path 1, color-1 on path 2, color-2 on path 1, color-2 on path 2) and compensate out all non-gas effects.

As discussed, improvements to this measurement scheme to further improve stability (including using the 2-color LED also as a 2-color detector to provide further stability enhancement).

FIG. 8A-8C exemplifies an application embodiment of this disclosure in which the two-color LED is placed in an optical path that includes a two-passband optical filter, which results in a narrow spectrum of light overlapping the gas absorption peaks, which is heavily illuminated by one of the LED emission colors, as well as a second passband optical filter that is designed to transmit light in a narrow region for which there are no emission peaks from the analyte gas, nor other nuisance gases, and is heavily illuminated by the other LED emission color.

In this particular example, parabolic mirrors 830 and 850 are used as a means to produce two separate optical paths, but this can be done in a variety of manners, including beamsplitters, or waveguides, etc. The main detection 860 and reference detector 860 measure the incident light from the two optical paths which have differing path lengths, with the main detector path length being longer than the reference detector path length. In total, four measurements are taken: color-1 incident on main detector, color-1 incident on reference detector, color-2 incident on main detector, and color-2 incident on reference 2. Defining P₁(λ, T) as the power spectrum of color-1 as a function of wavelength, denoted as λ, and temperature, denoted as T, and P₂(λ,T) as the equivalent for color-2, then the optical filter can be defined as a filter operator, Â, where:

$$\hat{A} P ( λ ) = \int f ( λ ) * P ( λ ) d λ ,$$

where f(λ) is the filter transmission as a function of wavelength λ. Using this operator definition, the four measurements of the system 800 can be described in a matrix formalism, where the transmission of color-1 on the main optical path is T₁^{main} and on the reference optical path is T₁^{ref}, and the same formalism is used for color-2. The output of the four measurements can be described by a four-dimensional vector, y:

$$\hat{A} [ \begin{matrix}{T}_{1}^{main} ( T ) & 0 \\ {T}_{1}^{ref} ( T ) & 0 \\ 0 & {T}_{main} ( T ) \\ 0 & {T}_{ref} ( T )\end{matrix} ] * [ \begin{matrix}{P}_{1} ( T ) \\ {P}_{2} ( T )\end{matrix} ] = [ \begin{matrix}{y}_{1} \\ {y}_{2} \\ {y}_{3} \\ {y}_{4}\end{matrix} ] .$$

Assuming color-1 is the absorbing channel (the color with the wavelength spectrum intended to be absorbed by the gas), then T₁^{main} and T₁^{ref} may change according to the gas concentration, while T₂^{main} and T₂^{ref} may not, or at least change to a much lesser extent. In the absence of gas, they may still depend on the temperature and other environmental factors. The goal of this system with four separate measurements is to compensate out these factors, and obtain a figure that is dependent only on gas concentration.

We define the ratio r₁ as the ratio of main/reference detector signal for color-1, and r₂ as the ratio of main/reference detector signal for color-2, such that:

$${r}_{1} = {y}_{1} / {y}_{2} , {r}_{2} = {y}_{3} / {y}_{4} .$$

Then, a full-ratio, r_{f}, can be defined as the ratio of r₁ to r₂, which is interpreted as the signal of the sensor.

$${r}_{f} = \frac{{r}_{1}}{{r}_{2}} ,$$

$${r}_{f} = \frac{{T}_{1}^{main} ( T ) * \hat{A} {P}_{1} ( T ) * {T}_{2}^{ref} ( T ) * \hat{A} {P}_{2} ( T )}{{T}_{1}^{ref} ( T ) * \hat{A} {P}_{1} ( T ) * {T}_{2}^{main} ( T ) * \hat{A} {P}_{2} ( T )} ,$$

$${r}_{f} = \frac{{T}_{1}^{main} ( T )}{{T}_{2}^{main} ( T )} * \frac{{T}_{2}^{ref} ( T )}{{T}_{1}^{ref} ( T )} .$$

This signal is independent of temperature and other effects if the transmission of the main path is the same for both colors, and the transmission of the reference path is also the same for both colors. The present disclosure provides techniques to minimize the differences in the optical path between the two colors. In the limit where the paths are equivalent for the two colors, then T₁^{main}(T)=T₂^{main}(T), and T₁^{ref}(T)=T₂^{ref}(T), then:

$${r}_{f} = 1 .$$

Hence, r_{f} can be used as a sensor output that, for a well-designed system, remains near 1 and for an ideal system, remains precisely 1. While temperature is expressed as the independent variable in this example, such temperature-dependent variables can also depend on other factors such as strain, humidity, device aging, differences in parameters of the main and reference detector. In all cases, to the extent that these effects are similar for both colors, these factors are cancelled from the ratio and compensated.

In the presence of gas at concentration c, however, this full-ratio changes, via the transmission term changing for both main and ref. The transmission as a function of concentration is described by Beer-Lambert Law. It is easiest to describe the new transmission terms as the term in the absence of gas attenuated by a Beer-Lambert exponential modifier:

$${T}_{1}^{main} ( T , c ) = {T}_{1}^{main} ( T , c = 0 ) * {e}^{( - {ε}_{1} {l}_{m} c )} ,$$

$${T}_{1}^{ref} ( T , c ) = {T}_{1}^{, ref} ( T , c = 0 ) * {e}^{( - {ε}_{1} {l}_{r} c )} ,$$

$${T}_{2}^{main} ( T , c ) = {T}_{2}^{main} ( T , c = 0 ) * {e}^{( - {ε}_{2} {l}_{m} c )} ,$$

$${T}_{2}^{, ref} ( T , c ) = {T}_{2}^{, ref} ( T , c = 0 ) * {e}^{( - {ε}_{2} {l}_{r} c )} ,$$

where ε₁ is the effective absorption coefficient of color1, ε₂ is the effective absorption coefficient of color-2, lₘ is the length of the main optical path, and lᵣ is the length of the reference optical path.

Keeping with the ideal case of matched optical paths between the colors, then the full-ratio, which is 1 in the absence of gas, becomes the following in the presence of gas at a concentration c:

$${r}_{f} = \frac{{e}^{( - {ε}_{1} {l}_{m} c )} * {e}^{( - {ε}_{1} {l}_{r} c )}}{{e}^{( - {ε}_{1} {l}_{r} c )} * {e}^{( - {ε}_{1} {l}_{m} c )}} ,$$

$${r}_{f} = {e}^{( - Δ εΔ l , c )} .$$

Accordingly, the full ratio is analogous to Beer-Lambert-law, where the path length term is replaced by a differential path length Δl that represents the difference in path length between the main and reference path, and the effective absorption coefficient is replaced by a differential effective absorption coefficient Δε that represents the difference in effective absorption coefficient between color-1 and color-2.

In real-world systems, the sensor has a baseline signal (in the absence of gas), which drifts over all environmental conditions. One skilled in art can appreciate the signal means the sensor signal in gas, over the total range of the baseline (no gas) over all operating conditions. And for the purpose of the present disclosure, everything not gas absorption (like mechanical deformation, temperature drifts, etc.) is noise. As such, noise may comprise but is not limited to the shot noise/Johnson noise.

Johnson-Nyquist noise (thermal noise, Johnson noise, or Nyquist noise) is the electronic noise generated by the thermal agitation of the charge carriers (usually the electrons) inside an electrical conductor at equilibrium, which happens regardless of any applied voltage. Thermal noise is present in all electrical circuits, and in sensitive electronic equipment such as radio receivers can drown out weak signals, and can be the limiting factor on sensitivity of an electrical measuring instrument.

Thermal noise increases with temperature. Some sensitive electronic equipment such as radio telescope receivers are cooled to cryogenic temperatures to reduce thermal noise in their circuits. The generic, statistical physical derivation of this noise is called the fluctuation—dissipation theorem, where generalized impedance or generalized susceptibility is used to characterize the medium.

Thermal noise in an ideal resistor is approximately white, meaning that the power spectral density is nearly constant throughout the frequency spectrum (however see the section below on extremely high frequencies). When limited to a finite bandwidth, thermal noise has a nearly Gaussian amplitude distribution.

The present disclosure ameliorates other types of noise, for example, stemming from thermal drift, self-heating and voltage coefficient. Voltage coefficient is the change in resistance with applied voltage. This is entirely different and in addition to the effects of self-heating when power is applied.

Categorizing this baseline drift as noise, then at a given concentration of gas, the signal-to-noise ratio is:

$$SNR = \frac{mean ( {r}_{f} ( no gas ) ) - {r}_{f} ( gas )}{range ( {r}_{f} ( no gas ) over all environmental conditions )} ,$$

$$SNR = \frac{1 - {e}^{( - Δ ε . Δ l . c )}}{range [ \frac{{T}_{1}^{main} ( T )}{{T}_{2}^{main} ( T )} * \frac{{T}_{2}^{ref} ( T )}{{T}_{1}^{ref} ( T )} ]} .$$

There are two factors that may limit the SNR. First, is the matching of the terms for the two colors in the denominator. As stated prior, in a perfect system, the term in the dominator remains 1 and so its range is 0. In reality, there are differences due to slight differences in the colors' optical path as described prior. The greater these differences are, the greater the ratio will vary from 1 in its operating environment, and hence the greater the baseline will change over conditions. This brings down the SNR and affects the minimum detectable concentration accordingly. Hence, the need for the T^{ref} and T^{main} terms to be as similar as possible for both colors.

Secondly, the numerator controls the SNR as well. The differential path length Δl is limited by the package size. The differential absorption term Δε may be maximized to maximize SNR. The effective absorption coefficient of each channel is defined by:

$${ε}_{1 , 2} = \frac{\int f ( λ ) * {P}_{1 , 2} ( λ , T ) * {ε}_{gas} ( λ ) d λ}{f ( λ ) * {P}_{1 , 2} ( λ , T ) d λ} ,$$

where ε_{gas} is the gas absorption coefficient over wavelength, f is the filter transmission as before, and P_{1,2} is the spectrum of the color for each color.

The effective absorption is effectively the weighted average of the absorption coefficient over the entire spectrum of light that is transmitted it through the filter. The differential absorption is then:

$$Δ ε = {ε}_{1} - {ε}_{2} = \frac{\int f ( λ ) * {P}_{1} ( λ , T ) * {ε}_{gas} ( λ ) d λ}{f ( λ ) * {P}_{1} ( λ , T ) d λ} - \frac{\int f ( λ ) * {P}_{2} ( λ , T ) * {ε}_{gas} ( λ ) d λ}{f ( λ ) * {P}_{2} ( λ , T ) d λ} ,$$

where the subscript 1 refers to color-1 and the subscript 2 refers to color-2, following the earlier convention where color-1 is the color heavily absorbed by gas and color-2 is the non-absorbing reference color. In order to maximize this differential absorption term Δε, the first term may be maximized and the second term may be minimized. Part of maximizing Δε is to ensure the absorbing color passband is narrow enough that most of the transmitted light is overlapping with an absorption peak.

This may be true, even in a one-color system. The unique complication from a 2-color system is ensuring that most of the light from color-1 is transmitted through that absorption passband, and very little is transmitted through the other reference passband. In minimizing the second term of the differential absorption, the opposite is true: for color-2, the differential absorption term is maximized when most of the light from color-2 is transmitted through the reference passband and very little is transmitted through the main passband.

Therefore, for a given filter, the SNR is maximized by maximizing the differential absorption coefficient, which is maximized by maximizing a color-1 passband ratio, and a color-2 passband ratio defined by

$${r}_{p}^{( 1 )} = \frac{{\int }^{absorbing passband} f ( λ ) * {P}_{1} ( λ , T ) d λ}{{\int }^{reference passband} f ( λ ) * {P}_{1} ( λ , T ) d λ} ,$$

$${r}_{p}^{( 2 )} = \frac{{\int }^{reference passband} f ( λ ) * {P}_{2} ( λ , T ) d λ}{{\int }^{absorbing passband} f ( λ ) * {P}_{2} ( λ , T ) d λ} .$$

FIG. 8 graphically illustrates an exemplary light output spectrum with filter transmission in a differential path length measurement system, in accordance with others embodiments of the disclosure provided herein. FIG. 8 shows an example design of a dual-passband filter spectrum, overlayed with an example LED spectrum for two color channels emitted from the dual-color LED.

The absorbing color is chosen to have its spectrum peaked at the gas absorption max and aligned with the corresponding filter passband (in this example, for CH4 detection around 4.3 μm wavelength). The reference passband in this case is at a longer wavelength, and the reference color is chosen to be even longer than that so as to lower the fraction of light that is short enough wavelength to transmit through the absorbing passband, in order to increase rₚ⁽²⁾ while still maintaining an adequate optical power.

An important tradeoff exists where having closer spectra result in more similar optical paths, but also decreased passband ratios. Therefore, additional embodiments exist that can improve performance by improving this tradeoff.

If one color's passband ratio is significantly lower than the other, then it may limit the differential absorption term more than the other color. The longer-wavelength color is expected then to have the limiting passband ratio, as the emission spectrum tends to be noticeably asymmetric in the MWIR/LWIR wavelength range and less-steep on the shorter wavelength side, due to radiative recombination between thermally energized electrons and holes above the band-edge.

Hence, the longer wavelength color will typically have a poorer passband ratio, since the spectrum may not fall off as sharply with wavelength between the two filter passbands. Any ability to sharpen the spectrum of the longer-wavelength color on the short wavelength side, either physically or algorithmically, may result in a better passband ratio for that color and hence a better SNR. This is true regardless of whether the longer wavelength color is the absorbing color or the reference color.

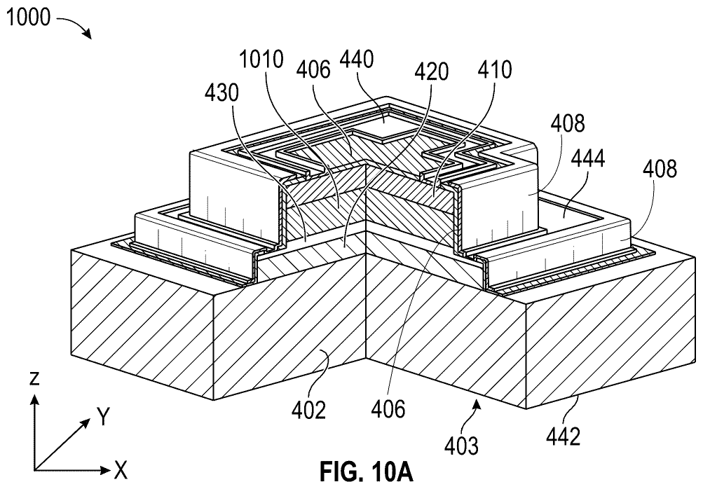

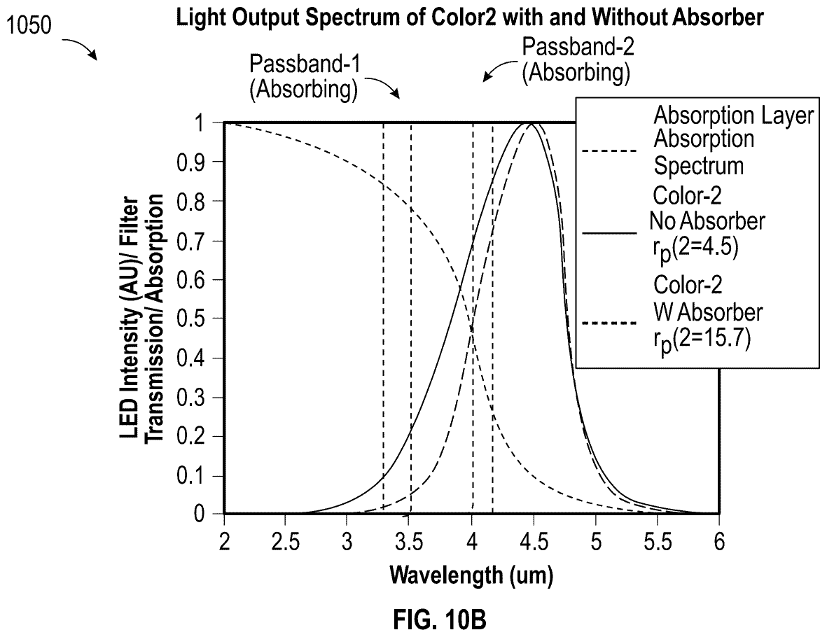

FIG. 10A depicts an exemplary cross-cut perspective of a monolithically integrated, two-color device 1000, in accordance with one or more embodiments of the disclosure provided herein. The device 1000 is similar to the devices 400 in many respects. For simplicity, FIG. 10A may use the same reference numerals as in FIG. 4 to refer to the same or analogous elements; for brevity, a discussion of these elements is not repeated, and these elements may take the form of any of the embodiments disclosed herein. In the present embodiment shown in FIG. 10A, spectral overlap is improved by having an absorbing layer 1010 in the path of the longer-wavelength light (from the lower active region 420). That is, the absorbing material in the layer 1010 can absorb the shorter wavelength light emission of the upper active region 410.

It can be constructed from the superlattice designed to have an intermediate bandgap between the two active regions 410 and 420, or can be a binary or alloy semiconductor designed to be part of the epitaxial stack and intermediate in bandgap between the upper and lower active regions. In doing so, it may have a material absorption coefficient that absorbs more of the short-wavelength tail of the light spectrum, sharpening it and lowering the spectral overlap. Assuming a top-side emitting device, it should be between the two active layers 410 and 420 so that the shorter wavelength light has a path to emission that does not involve the absorbing layer 1010.

The absorber layer 1010 and the middle (spreading/contact) layer 430 can be made the same layer. FIG. 10B illustrates an exemplary spectrum 1050 of the associate monolithically integrated, two-color device, in accordance with one or more embodiments of the disclosure provided herein. FIG. 10B shows the improvement in a typical example in which a dual-passband optical filter is used in the optical path. The figure of merit, rp⁽²⁾, describes the optical power in the longer wavelength passband from the longer—wavelength light as a ratio to the optical power in the shorter-wavelength passband from the same light source.

An optical filter need-not be used and the overlap is still improved. This addition of the absorber layer increases this ratio, meaning less spectral overlap. This ratio tends to be the limiting ratio, compared to rp⁽¹⁾ which describes the identical scenario for the shorter-wavelength color. Especially in the SWIR/MWIR/LWIR range, at temperatures in the room-temperature range, the emission spectra from a LED is asymmetric and tends to have a longer tail on the short-wavelength side, due to thermal energy of electrons and holes. Therefore, the overlap of the longer-wavelength color into the shorter wavelength region that limits the minimization of spectral overlap.

In some embodiments, the vertical structure 404 of any of the devices 400, 500, 600, 700, or 900 may include an electrically conductive material (e.g., the electrically conductive material 408 discussed above with reference to FIG. 4) covering all areas and sidewalls of the vertical structure 404 except for a window at a top surface of the vertical structure 404 for light emission from the upper active region 410 and the lower region 420. Referring to the example shown in FIG. 4A, the electrically conductive material 408 is disposed along sidewalls of the vertical structure 404 and areas on top of the portion of the middle region 430 that is extending (offset) from the upper active region 410 as shown by 409.

It is also possible to use such a configuration in the opposite sense. For instance, the same 2-color LED structure can be operated as a dual-band photodetector. The detector will output two signals: the current across the top and mid-contact gives the photocurrent from the upper superlattice, which assuming the wider bandgap, will largely only be affected by light in the shorter wavelength passband, and reject light in the longer wavelength passband. The current across the mid and bottom contact gives the photocurrent across the lower superlattice, which if the smaller bandgap superlattice, will have a spectral responsivity that covers both bands, and will hence be affected by light in both bands.

If the detectors are used in photovoltaic mode instead of photoconductive mode, then the voltage signals across the terminals may be used instead of current, and all other aspects work the same. Using this on the detector side in combination with a 2-color LED improves the spectral overlap of the longer wavelength color onto the shorter wavelength regime, by taking the difference between the two sets of measurements for that color, which partly subtracts the light from the longer wavelength color that came through the shorter wavelength passband. This effectively allows for an algorithmic improvement of the spectral overlap.

Alternatively, the dual band photodetector can be designed with an absorbing region in the same manner as with the LED. This can achieve more spectral separation of the two channels. This can be done with the same structure shown in FIG. 10A. The wider bandgap superlattice is on top, with an intermediate bandgap absorbing region and the lower bandgap superlattice at the bottom. The upper superlattice channel sees more light from the shorter wavelength passband, and the lower superlattice channel sees more light from the longer wavelength channel. For the shorter wavelength color, the upper superlattice channel is used to take the measurements, or the difference between the upper and lower superlattice channels is used. For the other color, the lower superlattice is used, or the difference of lower signal minus upper signal.

Any combination of these approaches to isolation of the spectra can be used and performance will improve in a summative manner. Further, since the color passband ratios have a temperature dependence, these embodiments can be used to increase the ratios over the entire temperature range to ensure that the lowest ratio in the operating temperature range remains acceptable.

With this method, direct calibration free measurement of gas concentration is achieved. The direct calibration free measurement can utilize the knowledge of optical path length and average gas absorption α_{gas}. Note that for many popular gases such as CO₂ or CH4 etc. absorption cross-section can be calculated for a given LED and optical filter. In general, the second LED and the first LED after passing thru the filter can both have common absorption regions. In which case, the common absorption region may still be cancelled.

In practice, changes in the optical path lead to changes in the measured intensity that can't be distinguished from changes due to gas absorption (even after using DPL method). These include: Vibration; Temperature induced changes in size and distortion of the optical surfaces; Humidity induced changes in size and distortion of the optical surfaces; Changes in the reflectance of the surfaces; and Changes in the responsivity of the photodiode. The embodiments presented herein ameliorate these error and noise stemming thereof.

While the discussion has used a specific optical module by way of example to describe the disclosed techniques, but it is not limited to any particular optical arrangement of beamsplitters and collimation optics. It is to be understood that the measurement of the four parameters is independent of how differential path length is specifically arranged. There are many cases in which one needs to measure extremely low concentration of a gas.

In this case, the optical path length should be long to provide sufficient absorption. But longer differential path length is even more likely to suffer from mechanical changes in the optical collection efficiency as environment changes byway of temperature or stress or humidity etc. And at the same time, one needs to measure even smaller changes as gas concentration is low.

The method disclosed herein becomes even more powerful for ultra-sensitive absorption measurement as it fully compensates for the mechanical as well as changes in the LED, PD, amplifiers etc. leaving only the absorption of gas as measured parameter. When perfected, the solution discussed in the present disclosure can be used to directly calibrate the gas concentration based directly on the first principle measurement.

Historically, in most cases, the inherent stability over environment is never achieved by the physical device but rather this is done by long and arduous calibration. A look-up table is built to compensate the expected changes by measuring environmental parameters like temperature and humidity. For ultra-precise measurement, the entire device is temperature stabilized. We are able to achieve this without either of these costly and laborious measures.

ASICs are used to process the detector signals while processing any necessary ratios, in one or more embodiments. An application-specific integrated circuit is an integrated circuit (IC) chip customized for a particular use, rather than intended for general-purpose use.

Other circuits are not beyond the scope of the current disclosure, such as, FPGAs, ADCs and AFEs. A field-programmable gate array (FPGA) is an integrated circuit designed to be configured by a customer or a designer after manufacturing—hence the term “field-programmable.” A field-programmable gate array (FPGA) is an integrated circuit designed to be configured by a customer or a designer after manufacturing—hence the term “field-programmable.” An analog-to-digital converter (ADC, A/D, or A-to-D) is a system that converts an analog signal, such as a sound picked up by a microphone or light entering a digital camera, into a digital signal. An analog front-end (AFE or analog front-end controller AFEC) is a set of analog signal conditioning circuitry that uses sensitive analog amplifiers, often operational amplifiers, filters, and sometimes application-specific integrated circuits for sensors, radio receivers, and other circuits to provide a configurable and flexible electronics functional block needed to interface a variety of sensors to an antenna, analog-to-digital converter or, in some cases, to a microcontroller.

### SELECT EXAMPLES

Example 1 provides an apparatus for optical differential path length gas detection comprising a first light source producing a first light centered at a first wavelength, a second light source producing a second light centered at a second wavelength, wherein the light produced from the sources are substantially coaxial.

Example 2 provides for the optical differential path length gas detector according to any of the preceding and/or proceeding examples further comprising a circuit configured to calculate a ratio of signals which represent measured intensities of the first and second light.

Example 3 provides for the optical differential path length gas detector according to any of the preceding and/or proceeding examples, wherein the circuit is an ASIC.

Example 4 provides for the optical differential path length gas detector according to any of the preceding and/or proceeding examples, wherein the circuit is an AFE.

Example 5 provides for the optical differential path length gas detector according to any of the preceding and/or proceeding examples further comprising a controller configured to control the current to the first and second light source.

Example 6 provides for the optical differential path length gas detector according to any of the preceding and/or proceeding examples further comprising a first photodetector configured to detect light centered at the first wavelength, the first photodetector producing a first signal indicative of measured intensity.

Example 7 provides for the optical differential path length gas detector according to any of the preceding and/or proceeding examples further comprising a first photodetector configured to detect light centered at the second wavelength, the second photodetector producing a second signal indicative of measured intensity.

Example 8 provides for the optical differential path length gas detector according to any of the preceding and/or proceeding examples further comprising a circuit configured to calculate a first ratio based at least on the first and second signals.

Example 9 provides for the optical differential path length gas detector according to any of the preceding and/or proceeding examples, wherein the circuit is further configured to calculate a ratio of ratios based at least on the first ratio.

Example 10 provides for the optical differential path length gas detector according to any of the preceding and/or proceeding examples further comprising a second filter configured to pass the first light.

Example 11 provides for the optical differential path length gas detector according to any of the preceding and/or proceeding examples further comprising a time multiplexer, wherein the time multiplexer is configured alternate between first and second signals.

Example 12 provides for an apparatus for optical differential path length gas detection comprising a first light source producing a first light cone centered at a first wavelength, a second light source producing a second light cone centered at a second wavelength, and a light filter disposed proximally to the first light source and configured to pass the second light, wherein, the first and second light cones substantially overlap.

Example 13 provides for the optical differential path length gas detector according to any of the preceding and/or proceeding examples, wherein the first light source is disposed directly adjacent to the second light source.

Example 14 provides for the optical differential path length gas detector according to any of the preceding and/or proceeding examples, wherein the first light source is disposed directly on top of the second light source.

Example 15 provides for the optical differential path length gas detector according to any of the preceding and/or proceeding examples further comprising a circuit configured to calculate a first ratio of signals which represent measured intensities of the first and second light.

Example 16 provides for the optical differential path length gas detector according to any of the preceding and/or proceeding examples, wherein the circuit is further configured to calculate a ratio of ratios based at least on the first ratio.

Example 17 provides for the optical differential path length gas detector according to any of the preceding and/or proceeding examples, wherein the first and second light sources are LEDs.

Example 18 provides for the optical differential path length gas detector according to any of the preceding and/or proceeding examples further comprising a controller configured to control the current to the first and second light source.

Example 19 provides for the optical differential path length gas detector according to any of the preceding and/or proceeding examples further comprising a second filter configured to pass the second light.

Example 20 provides for a method for calculating optical differential path length gas detection comprising emitting a first light from a first LED, the first light centered at a first wavelength; emitting a second light from a second LED, the second light centered at a second wavelength, reflecting the second light off the first LED, measuring the first light, measuring the second light; and calculating a ratio of ratios based at least on the measurement of the first and second light.

Example 21 provides a multi-wavelength emitting structure including a substrate; and a vertical structure over the substrate and extending vertically away from the substrate along an axis, the vertical structure including a first active region including one or more cascade stages of superlattices for light emission at a first wavelength; a second active region including one or more cascade stages of superlattices for light emission at a second wavelength different from the first wavelength, where the second active region is closer to the substrate than the first active region and spaced apart from the first active region; and an electrically conductive material along sidewalls of at least one of the first active region or the second active region.

Example 22 provides for the multi-wavelength emitting structure according to any of the preceding and/or proceeding examples, where one of the first active region or the second active region absorbs light from the other one of the first active region or the second active region.

Example 23 provides for the multi-wavelength emitting structure according to any of the preceding and/or proceeding examples, where the electrically conductive material is a first electrically conductive material, the vertical structure further includes a second electrically conductive material, and the first active region and the second active region are connected by the electrically conductive material.

Example 24 provides for the multi-wavelength emitting structure according to any of the preceding and/or proceeding examples, where the second electrically conductive material includes at least one of gallium antimonide (GaSb), indium arsenide (InAs), an alloy, or a superlattice.

Example 25 provides for the multi-wavelength emitting structure according to any of the preceding and/or proceeding examples, where along the axis, a polarity of the first active region is opposite to a polarity of the second active region.

Example 26 provides for the multi-wavelength emitting structure according to any of the preceding and/or proceeding examples, where one of the first active region or the second active region has a p-n configuration or a p-i-n configuration, and the other one of the first active region or the second active region has a n-p configuration or a n-i-p configuration.

Example 27 provides for the multi-wavelength emitting structure according to any of the preceding and/or proceeding examples, further including a first terminal and a second terminal, each including a metal layer; where the first terminal is in contact with the first active region, and the second terminal is in contact with the substrate.

Example 28 provides for the multi-wavelength emitting structure according to any of the preceding and/or proceeding examples, further including a third terminal including a metal layer, where the vertical structure further includes a middle region between the first active region and the second active region, and the third terminal is in contact with the middle region.

Example 29 provides for the multi-wavelength emitting structure according to any of the preceding and/or proceeding examples, where the vertical structure further includes an electrically conductive material covering all areas and sidewalls of the vertical structure except for a window at a first surface of the vertical structure for light emission from the first and second active regions, the first surface is opposite to a second surface of the vertical structure that is adjacent to the substrate.

Example 30 provides for the multi-wavelength emitting structure according to any of the preceding and/or proceeding examples, where the vertical structure further includes a middle region between the first active region and the second active region, the middle region including an absorbing material that absorbs a shorter wavelength light emission of the first active region or the second active region.

Example 31 provides a multi-wavelength photodetector structure including a substrate; and a vertical structure over the substrate and extending away from the substrate along an axis, the vertical structure including a first active region including one or more cascade stages of superlattices for light detection at a first wavelength; a second active region including one or more cascade stages of superlattices for light detection at a second wavelength different from the first wavelength, where the second active region is closer to the substrate than the first active region and spaced apart from the first active region; and an electrically conductive material along sidewalls of at least one of the first active region or the second active region.

Example 32 provides for the multi-wavelength photodetector structure according to any of the preceding and/or proceeding examples, where the electrically conductive material is a first electrically conductive material; the vertical structure further includes a middle region between the first active region and the second active region; and the middle region includes a second electrically conductive material.

Example 33 provides for the multi-wavelength photodetector structure according to any of the preceding and/or proceeding examples, where along the axis, a polarity of the first active region is opposite to a polarity of the second active region.

Example 34 provides for the multi-wavelength photodetector structure according to any of the preceding and/or proceeding examples, further including a first terminal and a second terminal, each including a metal layer; where the first terminal is in contact with the first active region, and the second terminal is in contact with the substrate.

Example 35 provides for the multi-wavelength photodetector structure according to any of the preceding and/or proceeding examples, further including a first terminal, a second terminal, and a third terminal, each including a metal layer; where the first terminal is in contact with the first active region, the second terminal is in contact with the substrate, the vertical structure further includes a middle region between the first active region and the second active region, and the third terminal is in contact with the middle region.

Example 36 provides for the multi-wavelength photodetector structure according to any of the preceding and/or proceeding examples, where the vertical structure further includes a middle region between the first active region and the second active region, the middle region including an absorbing material that absorbs light of a shorter wavelength of the first wavelength or the second wavelength.

Example 37 provides for the multi-wavelength photodetector structure according to any of the preceding and/or proceeding examples, where the vertical structure further includes at least one of a third active region including one or more cascaded stages of superlattice for light detection at the first wavelength; and a fourth active region including one or more cascaded stages of superlattice for light detection at the second wavelength, where a sensing ratio between the first active region and the second active region is different than a sensing ratio between the third active region and the fourth active region.

Example 38 provides an integrated circuit (IC) device for medium wavelength infrared (MWIR) or long wavelength infrared (LWIR), the device including a substrate; and an epitaxial structure over the substrate and extending away from the substrate, the epitaxial structure including a first active region including one or more cascade stages of superlattices for light emission at a first center wavelength; a second active region including one or more cascade stages of superlattices for light emission at a second center wavelength different from the first center wavelength, where a distance from the second active region to the substrate is shorter than a distance from the first active region to the substrate; and a middle region between the first active region and the second active region, the middle region including an absorbing material to absorb at least a portion of a shorter wavelength light emission of the first active region or the second active region.

Example 39 provides for the IC device according to any of the preceding and/or proceeding examples, where the middle region further includes dopants to form one of a common anode or a common cathode for the first and second active regions.

Example 40 provides for the IC device according to any of the preceding and/or proceeding examples, where the middle region further includes dopants to form an anode for one of the first active region or the second active region and a cathode for the other one of the first active region or the second active region.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. For example, those of ordinary skill in the art will readily envision a variety of other means and/or structures for performing the function and/or obtaining the results and/or one or more of the advantages described herein, and each of such variations and/or modifications is deemed to be within the scope of the embodiments described herein.

Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The foregoing outlines features of one or more embodiments of the subject matter disclosed herein. These embodiments are provided to enable a person having ordinary skill in the art (PHOSITA) to better understand various aspects of the present disclosure. Certain well—understood terms, as well as underlying technologies and/or standards may be referenced without being described in detail. It is anticipated that the PHOSITA will possess or have access to background knowledge or information in those technologies and standards sufficient to practice the teachings of the present disclosure.

The PHOSITA will appreciate that they may readily use the present disclosure as a basis for designing or modifying other processes, structures, or variations for carrying out the same purposes and/or achieving the same advantages of the embodiments introduced herein. The PHOSITA will also recognize that such equivalent constructions do not depart from the spirit and scope of the present disclosure, and that they may make various changes, substitutions, and alterations herein without departing from the spirit and scope of the present disclosure.

The above-described embodiments may be implemented in any of numerous ways. One or more aspects and embodiments of the present application involving the performance of processes or methods may utilize program instructions executable by a device (e.g., a computer, a processor, or other device) to perform, or control performance of, the processes or methods.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above.

The computer readable medium or media may be transportable, such that the program or programs stored thereon may be loaded onto one or more different computers or other processors to implement various ones of the aspects described above. In some embodiments, computer readable media may be non-transitory media.

Note that the activities discussed above with reference to the FIGURES which are applicable to any integrated circuit that involves signal processing (for example, gesture signal processing, video signal processing, audio signal processing, analog-to-digital conversion, digital-to-analog conversion), particularly those that can execute specialized software programs or algorithms, some of which may be associated with processing digitized real-time data.

In some cases, the teachings of the present disclosure may be encoded into one or more tangible, non-transitory computer-readable mediums having stored thereon executable instructions that, when executed, instruct a programmable device (such as a processor or DSP) to perform the methods or functions disclosed herein. In cases where the teachings herein are embodied at least partly in a hardware device (such as an ASIC, IP block, or SoC), a non-transitory medium could include a hardware device hardware-programmed with logic to perform the methods or functions disclosed herein. The teachings could also be practiced in the form of Register Transfer Level (RTL) or other hardware description language such as VHDL or Verilog, which can be used to program a fabrication process to produce the hardware elements disclosed.

In example implementations, at least some portions of the processing activities outlined herein may also be implemented in software. In some embodiments, one or more of these features may be implemented in hardware provided external to the elements of the disclosed figures, or consolidated in any appropriate manner to achieve the intended functionality. The various components may include software (or reciprocating software) that can coordinate in order to achieve the operations as outlined herein. In still other embodiments, these elements may include any suitable algorithms, hardware, software, components, modules, interfaces, or objects that facilitate the operations thereof.

Any suitably-configured processor component can execute any type of instructions associated with the data to achieve the operations detailed herein. Any processor disclosed herein could transform an element or an article (for example, data) from one state or thing to another state or thing. In another example, some activities outlined herein may be implemented with fixed logic or programmable logic (for example, software and/or computer instructions executed by a processor) and the elements identified herein could be some type of a programmable processor, programmable digital logic (for example, an FPGA, an erasable programmable read only memory (EPROM), an electrically erasable programmable read only memory (EEPROM)), an ASIC that includes digital logic, software, code, electronic instructions, flash memory, optical disks, CD-ROMs, DVD ROMs, magnetic or optical cards, other types of machine-readable mediums suitable for storing electronic instructions, or any suitable combination thereof.

In operation, processors may store information in any suitable type of non-transitory storage medium (for example, random access memory (RAM), read only memory (ROM), FPGA, EPROM, electrically erasable programmable ROM (EEPROM), etc.), software, hardware, or in any other suitable component, device, element, or object where appropriate and based on particular needs. Further, the information being tracked, sent, received, or stored in a processor could be provided in any database, register, table, cache, queue, control list, or storage structure, based on particular needs and implementations, all of which could be referenced in any suitable timeframe.

Any of the memory items discussed herein should be construed as being encompassed within the broad term ‘memory.’ Similarly, any of the potential processing elements, modules, and machines described herein should be construed as being encompassed within the broad term ‘microprocessor’ or ‘processor.’ Furthermore, in various embodiments, the processors, memories, network cards, buses, storage devices, related peripherals, and other hardware elements described herein may be realized by a processor, memory, and other related devices configured by software or firmware to emulate or virtualize the functions of those hardware elements.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a personal digital assistant (PDA), a smart phone, a mobile phone, an iPad, or any other suitable portable or fixed electronic device.

Also, a computer may have one or more input and output devices. These devices can be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet.

Such networks may be based on any suitable technology and may operate according to any suitable protocol and may include wireless networks or wired networks.

Computer-executable instructions may be in many forms, such as program modules, executed by one or more computers or other devices.

Generally, program modules include routines, programs, objects, components, data structures, etc. that performs particular tasks or implement particular abstract data types. Typically, the functionality of the program modules may be combined or distributed as desired in various embodiments.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present application need not reside on a single computer or processor, but may be distributed in a modular fashion among a number of different computers or processors to implement various aspects of the present application.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Computer program logic implementing all or part of the functionality described herein is embodied in various forms, including, but in no way limited to, a source code form, a computer executable form, a hardware description form, and various intermediate forms (for example, mask works, or forms generated by an assembler, compiler, linker, or locator). In an example, source code includes a series of computer program instructions implemented in various programming languages, such as an object code, an assembly language, or a high-level language such as OpenCL, RTL, Verilog, VHDL, Fortran, C, C++, JAVA, or HTML for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

In some embodiments, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc.

Other components such as external storage, additional sensors, controllers for audio/video display, and peripheral devices may be attached to the board as plug-in cards, via cables, or integrated into the board itself. In another example embodiment, the electrical circuits of the FIGURES may be implemented as standalone modules (e.g., a device with associated components and circuitry configured to perform a specific application or function) or implemented as plug-in modules into application-specific hardware of electronic devices.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this disclosure.

In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

### Interpretation of Terms

All definitions, as defined and used herein, should be understood to control over dictionary definitions, definitions in documents incorporated by reference, and/or ordinary meanings of the defined terms. Unless the context clearly requires otherwise, throughout the description and the claims:
“comprise,” “comprising,” and the like are to be construed in an inclusive sense, as opposed to an exclusive or exhaustive sense; that is to say, in the sense of “including, but not limited to”.
“connected,” “coupled,” or any variant thereof, means any connection or coupling, either direct or indirect, between two or more elements; the coupling or connection between the elements can be physical, logical, or a combination thereof.
“herein,” “above,” “below,” and words of similar import, when used to describe this specification shall refer to this specification as a whole and not to any particular portions of this specification.
“or,” in reference to a list of two or more items, covers all of the following interpretations of the word: any of the items in the list, all of the items in the list, and any combination of the items in the list.
the singular forms “a”, “an” and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present) depend on the specific orientation of the apparatus described and illustrated. The subject matter described herein may assume various alternative orientations. Accordingly, these directional terms are not strictly defined and should not be interpreted narrowly.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined.

Elements other than those specifically identified by the “and/or” clause may optionally be present, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein, the term “between” is to be inclusive unless indicated otherwise. For example, “between A and B” includes A and B unless indicated otherwise.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke 35 U.S.C. § 112(f) as it exists on the date of the filing hereof unless the words “means for” or “steps for” are specifically used in the particular claims; and (b) does not intend, by any statement in the disclosure, to limit this disclosure in any way that is not otherwise reflected in the appended claims.

The present invention should therefore not be considered limited to the particular embodiments described above. Various modifications, equivalent processes, as well as numerous structures to which the present invention may be applicable, will be readily apparent to those skilled in the art to which the present invention is directed upon review of the present disclosure.

The invention claimed is:

1. A multi-wavelength emitting structure comprising:
a substrate; and
a vertical structure over the substrate and extending vertically away from the substrate along an axis, the vertical structure comprising:
a first active region including one or more cascade stages of superlattices for light emission at a first wavelength;
a second active region including one or more cascade stages of superlattices for light emission at a second wavelength different from the first wavelength, wherein the second active region is closer to the substrate than the first active region and spaced apart from the first active region; and
an electrically conductive material along sidewalls of at least one of the first active region or the second active region.

2. The multi-wavelength emitting structure of claim 1, wherein one of the first active region or the second active region absorbs light from the other one of the first active region or the second active region.

3. The multi-wavelength emitting structure of claim 1, wherein:
the electrically conductive material is a first electrically conductive material,
the vertical structure further comprises a second electrically conductive material, and
the first active region and the second active region are connected by the electrically conductive material.

4. The multi-wavelength emitting structure of claim 3, wherein the second electrically conductive material comprises at least one of gallium antimonide (GaSb), indium arsenide (InAs), an alloy, or a superlattice.

5. The multi-wavelength emitting structure of claim 1, wherein along the axis, a polarity of the first active region is opposite to a polarity of the second active region.

6. The multi-wavelength emitting structure of claim 1, wherein:
one of the first active region or the second active region has a p-n configuration or a p-i-n configuration, and
the other one of the first active region or the second active region has a n-p configuration or a n-i-p configuration.

7. The multi-wavelength emitting structure of claim 1, further comprising:
a first terminal and a second terminal, each including a metal layer,
wherein:
the first terminal is in contact with the first active region, and
the second terminal is in contact with the substrate.

8. The multi-wavelength emitting structure of claim 7, further comprising:
a third terminal including a metal layer,
wherein:
the vertical structure further comprises a middle region between the first active region and the second active region, and
the third terminal is in contact with the middle region.

9. The multi-wavelength emitting structure of claim 1, wherein:
the vertical structure further comprises an electrically conductive material covering all areas and sidewalls of the vertical structure except for a window at a first surface of the vertical structure for light emission from the first and second active regions, and
the first surface is opposite to a second surface of the vertical structure that is adjacent to the substrate.

10. The multi-wavelength emitting structure of claim 1, wherein the vertical structure further comprises a middle region between the first active region and the second active region, the middle region including an absorbing material that absorbs a shorter wavelength light emission of the first active region or the second active region.

11. A multi-wavelength photodetector structure comprising:
a substrate; and
a vertical structure over the substrate and extending away from the substrate along an axis, the vertical structure comprising:
a first active region including one or more cascade stages of superlattices for light detection at a first wavelength;
a second active region including one or more cascade stages of superlattices for light detection at a second wavelength different from the first wavelength, wherein the second active region is closer to the substrate than the first active region and spaced apart from the first active region; and
an electrically conductive material along sidewalls of at least one of the first active region or the second active region.

12. The multi-wavelength photodetector structure of claim 11, wherein:
the electrically conductive material is a first electrically conductive material,
the vertical structure further comprises a middle region between the first active region and the second active region, and
the middle region includes a second electrically conductive material.

13. The multi-wavelength photodetector structure of claim 11, wherein along the axis, a polarity of the first active region is opposite to a polarity of the second active region.

14. The multi-wavelength photodetector structure of claim 11, further comprising:
a first terminal and a second terminal, each including a metal layer,
wherein:
the first terminal is in contact with the first active region, and
the second terminal is in contact with the substrate.

15. The multi-wavelength photodetector structure of claim 11, further comprising:
a first terminal, a second terminal, and a third terminal, each including a metal layer,
wherein:
the first terminal is in contact with the first active region,
the second terminal is in contact with the substrate,
the vertical structure further comprises a middle region between the first active region and the second active region, and
the third terminal is in contact with the middle region.

16. The multi-wavelength photodetector structure of claim 11, wherein the vertical structure further comprises a middle region between the first active region and the second active region, the middle region including an absorbing material that absorbs light of a shorter wavelength of the first wavelength or the second wavelength.

17. The multi-wavelength photodetector structure of claim 11, wherein:
the vertical structure further comprises at least one of:
a third active region comprising one or more cascaded stages of superlattice for light detection at the first wavelength, and
a fourth active region comprising one or more cascaded stages of superlattice for light detection at the second wavelength, and
a sensing ratio between the first active region and the second active region is different than a sensing ratio between the third active region and the fourth active region.

18. An integrated circuit (IC) device for medium wavelength infrared (MWIR) or long wavelength infrared (LWIR), the device comprising:
a substrate; and
an epitaxial structure over the substrate and extending away from the substrate, the epitaxial structure comprising:
a first active region including one or more cascade stages of superlattices for light emission at a first center wavelength;
a second active region including one or more cascade stages of superlattices for light emission at a second center wavelength different from the first center wavelength, wherein a distance from the second active region to the substrate is shorter than a distance from the first active region to the substrate; and
a middle region between the first active region and the second active region, the middle region including an absorbing material to absorb at least a portion of a shorter wavelength light emission of the first active region or the second active region.

19. The IC device of claim 18, wherein the middle region further includes dopants to form one of a common anode or a common cathode for the first and second active regions.

20. The IC device of claim 18, wherein the middle region further includes dopants to form an anode for one of the first active region or the second active region and a cathode for the other one of the first active region or the second active region.
